(19) United States
(12) Patent Application Publication
(10) Pub. No.: US 2025/0212585 A1
(43) Pub. Date: Jun. 26, 2025

(54) DISPLAY DEVICE

(71) Applicant: Samsung Display Co., LTD., Yongin-si (KR)

(72) Inventors: HYUNWOOK CHOI, Yongin-si (KR); SIWOO KIM, Yongin-si (KR); YONGJAE KIM, Yongin-si (KR); YEONHA BAEK, Yongin-si (KR); YOONJEE SHIN, Yongin-si (KR)

(21) Appl. No.: 18/980,027

(22) Filed: Dec. 13, 2024

(30) Foreign Application Priority Data
Dec. 21, 2023 (KR) 10-2023-0188425

(51) Int. Cl. H10H 29/49; H10H 29/39

(52) U.S. Cl. CPC H10H 29/49; H10H 29/39

(57) ABSTRACT

A display device includes: an active pattern; a first gate line; a power voltage line; a light emitting element; a first transistor electrically connected to the power voltage line and the light emitting element; and a second transistor electrically connected to the first gate line and including a first sub-transistor electrically connected to the first transistor and including a first sub-gate electrode and a second sub-transistor connected in series with the first sub-transistor and including a second sub-gate electrode spaced apart from the first sub-gate electrode. An area in which the first sub-gate electrode overlaps the active pattern in a plan view is greater than an area in which the second sub-gate electrode overlaps the active pattern in the plan view.

This application claims priority to Korean Patent Application No. 10-2023-0188425, filed on Dec. 21, 2023, and all the benefits accruing therefrom under 35 U.S.C. § 119, the content of which in its entirety is herein incorporated by reference.

### BACKGROUND

### 1. Field

Embodiments relate to a display device. More specifically, embodiments relate to a display device that provides visual information and an electronic device including the display device.

### 2. Description of the Related Art

A display device may include transistors and light emitting elements. The transistors may include a driving transistor. The driving transistor may generate a driving current based on a gate-source voltage of the driving transistor, and the light emitting element may emit light based on the driving current.

Leakage current occurred in the transistors may affect the gate-source voltage of the driving transistor, and may cause luminance deviation. The luminance deviation may be visible to a user, and may be intensified in a display device that performs variable frequency driving. In particular, when the display device changes from a high frequency to a low frequency, the luminance deviation may be visible to the user as a flicker.

### SUMMARY

Embodiments provide a display device with improved display quality.

Embodiments provide an electronic device including the display device.

A display device according to an embodiment of the present disclosure includes: an active pattern, a first gate line, a power voltage line, a light emitting element, a first transistor electrically connected to the power voltage line and the light emitting element, and a second transistor electrically connected to the first gate line and including a first sub-transistor electrically connected to the first transistor and including a first sub-gate electrode and a second sub-transistor connected in series with the first sub-transistor and including a second sub-gate electrode spaced apart from the first sub-gate electrode. An area in which the first sub-gate electrode overlaps the active pattern in a plan view is greater than an area in which the second sub-gate electrode overlaps the active pattern in the plan view.

In an embodiment, the first gate line may include a first line portion extending in a first direction and a first protrusion portion protruding from the first line portion in a second direction intersecting the first direction, the first sub-gate electrode may be a portion of the first protrusion portion, and the second sub-gate electrode may be a portion of the first line portion.

In an embodiment, a length of the first sub-gate electrode in the first direction may be longer than a length of the second sub-gate electrode in the second direction.

In an embodiment, a length of the first sub-gate electrode in the second direction may be longer than a length of the second sub-gate electrode in the second direction.

In an embodiment, a length of the first protrusion portion in the first direction may be longer than a length of the first line portion in the second direction.

In an embodiment, the display device may further include: a second gate line and a third transistor electrically connected to the second gate line and including a third sub-transistor electrically connected to the first transistor and including a third sub-gate electrode and a fourth sub-transistor connected in series with the third sub-transistor and including a fourth sub-gate electrode spaced apart from the third sub-gate electrode.

In an embodiment, an area in which the third sub-gate electrode overlaps the active pattern in the plan view may be greater than an area in which the fourth sub-gate electrode overlaps the active pattern in the plan view.

In an embodiment, a length of the third sub-gate electrode in the second direction may be longer than a length of the fourth sub-gate electrode in the second direction.

In an embodiment, the second gate line may include a second line portion extending in the first direction and a second protrusion portion protruding from the second line portion in the second direction, the third sub-gate electrode may be a portion of the second protrusion portion and the second line portion, and the fourth sub-gate electrode may be a portion of the second line portion.

In an embodiment, a length of the second protrusion portion and the second line portion in the second direction may be longer than a length of the second line portion in the second direction.

In an embodiment, the first sub-gate electrode, the second sub-gate electrode, the third sub-gate electrode, and the fourth sub-gate electrode may be disposed in the same layer.

In an embodiment, the second sub-transistor may be electrically connected to the first transistor through the first sub-transistor.

A display device according to an embodiment of the present disclosure includes: an active pattern, a gate layer disposed on the active pattern and including a first gate line and a second gate line, a conductive layer disposed on the gate layer and including a power voltage line, and a pixel electrode disposed on the conductive layer. The active pattern and the gate layer define a first transistor electrically connected to the power voltage line and the pixel electrode, a second transistor electrically connected to the first gate line and including a first sub-transistor electrically connected to the first transistor and including a first sub-gate electrode and a second sub-transistor connected in series with the first sub-transistor and including a second sub-gate electrode spaced apart from the first sub-gate electrode, and a third transistor electrically connected to the second gate line and including a third sub-transistor electrically connected to the first transistor and including a third sub-gate electrode and a fourth sub-transistor connected in series with the third sub-transistor and including a fourth sub-gate electrode spaced apart from the third sub-gate electrode. The conductive layer overlaps at least one of the first sub-transistor, the second sub-transistor, the third sub-transistor, or the fourth sub-transistor in a plan view.

In an embodiment, the power voltage line may overlap the first sub-transistor, the second sub-transistor, and the third sub-transistor in the plan view.

In an embodiment, the conductive layer may further include a data line, and the data line may overlap the fourth sub-transistor in the plan view.

In an embodiment, the pixel electrode may overlap at least one of the first sub-transistor, the second sub-transistor, the third sub-transistor, or the fourth sub-transistor in the plan view.

In an embodiment, the first gate line may include a first line portion extending in a first direction and a first protrusion portion protruding from the first line portion in a second direction intersecting the first direction, the first sub-gate electrode may be a portion of the first protrusion portion, and the second sub-gate electrode may be a portion of the first line portion.

In an embodiment, an area in which the first sub-gate electrode overlaps the active pattern in the plan view may be greater than an area in which the second sub-gate electrode overlaps the active pattern in the plan view.

In an embodiment, a length of the first sub-gate electrode in the first direction may be longer than a length of the second sub-gate electrode in the second direction.

In an embodiment, the second gate line may include a second line portion extending in a first direction and a second protrusion portion protruding from the second line portion in a second direction intersecting the first direction, the third sub-gate electrode may be a portion of the second protrusion portion and the second line portion, and the fourth sub-gate electrode may be a portion of the second line portion.

In an embodiment, an area in which the third sub-gate electrode overlaps the active pattern in the plan view may be greater than an area in which the fourth sub-gate electrode overlaps the active pattern in the plan view.

In an embodiment, a length of the third sub-gate electrode in the second direction may be longer than a length of the fourth sub-gate electrode in the second direction.

An electronic device according to an embodiment of the present disclosure includes: a display device and a power module that supplies power to the display device. The display device includes an active pattern, a first gate line, a power voltage line, a light emitting element, a first transistor electrically connected to the power voltage line and the light emitting element, and a second transistor electrically connected to the first gate line and including a first sub-transistor electrically connected to the first transistor and including a first sub-gate electrode and a second sub-transistor connected in series with the first sub-transistor and including a second sub-gate electrode spaced apart from the first sub-gate electrode. An area in which the first sub-gate electrode overlaps the active pattern in a plan view is greater than an area in which the second sub-gate electrode overlaps the active pattern in the plan view.

In a display device according to embodiments of the present disclosure, the display device may include a transistor including a first sub-transistor and a second sub-transistor. As a channel area of the first sub-transistor may have a relatively longer length than a channel area of the second sub-transistor, leakage current that occurs in the transistor may be reduced. In addition, as a conductive layer disposed on the transistor may shield an upper portion of the transistor, leakage current that occurs in the transistor due to external light may be reduced. Accordingly, an image may be displayed with uniform luminance, thereby effectively improving display quality of the display device.

### BRIEF DESCRIPTION OF THE DRAWINGS

FIG. 1 is a block diagram illustrating a display device according to an embodiment of the present disclosure.

FIG. 2 is a conceptual diagram illustrating a driving frequency of a display panel of FIG. 1.

FIG. 3 is a circuit diagram illustrating a pixel included in the display device of FIG. 1.

FIGS. 4, 5, 6, 7, 8, 9, 10, and 11 are diagrams illustrating a pixel included in the display device of FIG. 1.

FIGS. 12, 13, and 14 are diagrams illustrating a display device according to another embodiment of the present disclosure.

FIGS. 15, 16, and 17 are diagrams illustrating a display device according to still another embodiment of the present disclosure.

FIGS. 18, 19, and 20 are diagrams illustrating a display device according to yet another embodiment of the present disclosure.

FIG. 21 is a block diagram illustrating an electronic device according to an embodiment of the present disclosure.

FIG. 22 is a schematic diagram illustrating electronic devices according to embodiments of the present disclosure.

### DETAILED DESCRIPTION

The terminology used herein is for the purpose of describing particular embodiments only and is not intended to be limiting. As used herein, “a” “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

It will be understood that when an element is referred to as being “on” another element or “connected to” another element, it can be directly on or directly connected to the other element or intervening elements may be present therebetween. In contrast, when an element is referred to as being “directly on” another element, there are no intervening elements present.

Hereinafter, embodiments of the present disclosure will be described in more detail with reference to the accompanying drawings. The same reference numerals are used for the same components in the drawings, and redundant descriptions of the same components will be omitted.

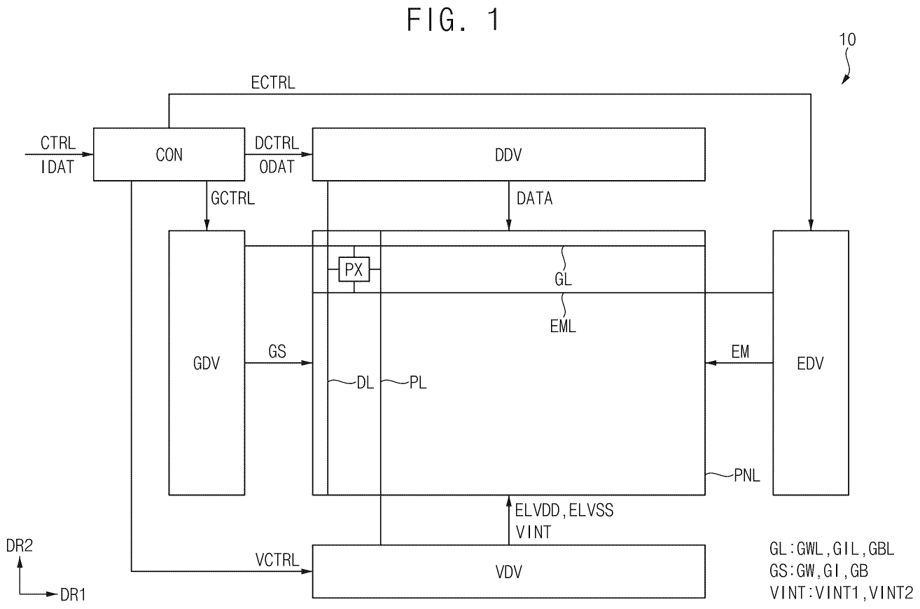

FIG. 1 is a block diagram illustrating a display device according to an embodiment of the present disclosure.

Referring to FIG. 1, a display device 10 may include a display panel PNL and a driver. The driver may include a gate driver GDV, a light emitting driver EDV, a data driver DDV, a voltage driver VDV, and a controller CON.

The display panel PNL may include a plurality of pixels PX electrically connected to a gate line GL, a light emitting line EML, a data line DL, and a voltage line PL. For example, the gate line GL may include a first gate line GWL, a second gate line GIL, and a third gate line GBL.

For example, the gate line GL and the light emitting line EML may extend in a first direction DR1. The data line DL and the voltage line PL may extend in a second direction DR2 intersecting the first direction DR1. For example, the second direction DR2 may be perpendicular to the first direction DR1.

Each of the pixels PX may be electrically connected to the gate driver GDV, the light emitting driver EDV, the data driver DDV, and the voltage driver VDV. Specifically, each of the pixels PX may be connected to the gate driver GDV through the gate line GL, may be connected to the light emitting driver EDV through the light emitting line EML, may be connected to the data driver DDV through the data line DL, and may be connected to the voltage driver VDV through the voltage line PL. Accordingly, each of the pixels PX may receive a gate signal GS, a light emitting signal EM, a data voltage DATA, a first power voltage ELVDD, a second power voltage ELVSS, and an initialization voltage VINT. For example, the gate signal GS may include a first gate signal GW, a second gate signal GI, and a third gate signal GB, and the initialization voltage VINT may include a first initialization voltage VINT1 and a second initialization voltage VINT2.

The gate driver GDV may receive a gate control signal GCTRL from the controller CON. The gate driver GDV may generate the gate signal GS based on the gate control signal GCTRL. The gate signal GS may be provided to each of the pixels PX through the gate line GL.

The light emitting driver EDV may receive a light emitting control signal ECTRL from the controller CON. The light emitting driver EDV may generate the light emitting signal EM based on the light emitting control signal ECTRL. The light emitting signal EM may be provided to each of the pixels PX through the light emitting line EML.

The data driver DDV may receive a data control signal DCTRL and output image data ODAT from the controller CON. The data driver DDV may generate the data voltage DATA based on the data control signal DCTRL and the output image data ODAT. The data voltage DATA may be provided to each of the pixels PX through the data line DL.

The voltage driver VDV may receive a voltage control signal VCTRL from the controller CON. The voltage driver VDV may generate the first power voltage ELVDD, the second power voltage ELVSS, and the initialization voltage VINT based on the voltage control signal VCTRL. The first power voltage ELVDD, the second power voltage ELVSS, and the initialization voltage VINT may be provided to each of the pixels PX through the voltage line PL.

The controller CON may receive a control signal CTRL and input image data IDAT from an external device (e.g., a GPU). The controller CON may generate the gate control signal GCTRL, the data control signal DCTRL, the output image data ODAT, the light emitting control signal ECTRL, and the voltage control signal VCTRL based on the control signal CTRL and the input image data IDAT. The controller CON may control the gate driver GDV, the light emitting driver EDV, the data driver DDV, and the voltage driver VDV.

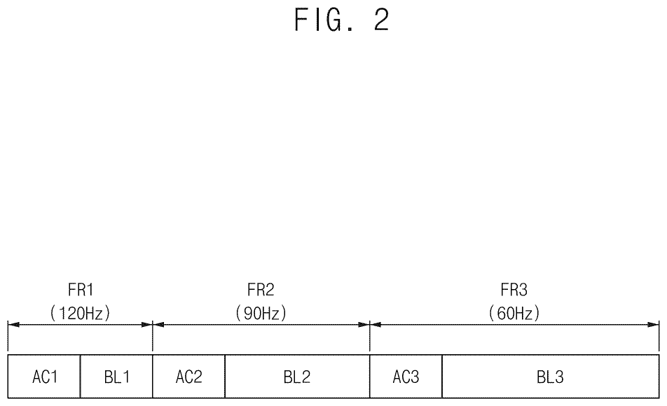

FIG. 2 is a conceptual diagram illustrating a driving frequency of a display panel of FIG. 1.

Referring to FIGS. 1 and 2, the display panel PNL may be driven at a variable frequency. A first frame FR1 may include a first active period AC1 and a first blank period BL1. The first blank period BL1 may follow the first active period AC1. A second frame FR2 may include a second active period AC2 and a second blank period BL2. The second active period AC2 may follow the first blank period BL1, and the second blank period BL2 may follow the second active period AC2. A third frame FR3 may include a third active period AC3 and a third blank period BL3. The third active period AC3 may follow the second blank period BL2, and the third blank period BL3 may follow the third active period AC3.

In an embodiment, the first frame FR1, the second frame FR2, and the third frame FR3 may have different frequencies. For example, as illustrated in FIG. 2, the first frame FR1 may have a frequency of about 120 Hz, the second frame FR2 may have a frequency of about 90 Hz, and the third frame FR3 may have a frequency of about 60 Hz.

In an embodiment, a length of the first active period AC1 may be the same as a length of the second active period AC2, and a length of the first blank period BL1 may be different from a length of the second blank period BL2. That is, a period of the first frame FR1 may be different from a period of the second frame FR2.

In an embodiment, the length of the second active period AC2 may be the same as a length of the third active period AC3, and the length of the second blank period BL2 may be different from a length of the third blank period BL3. That is, the period of the second frame FR2 may be different from a period of the third frame FR3.

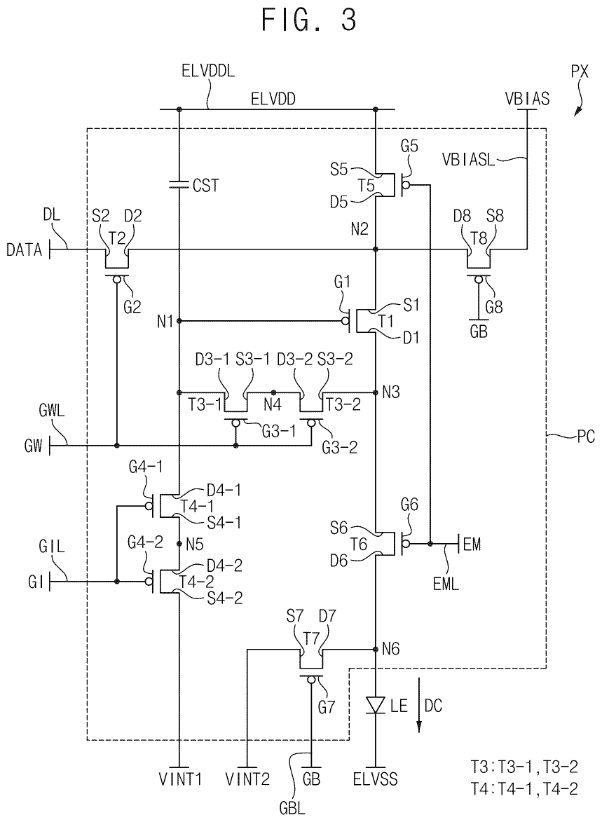

FIG. 3 is a circuit diagram illustrating a pixel included in the display device of FIG. 1.

Referring to FIGS. 1 and 3, the pixel PX may include a light emitting element LE and a pixel circuit PC electrically connected to the light emitting element LE. The pixel circuit PC may provide a driving current DC to the light emitting element LE.

The light emitting element LE may emit light based on the driving current DC. The light emitting element LE may include a first electrode (e.g., an anode electrode) and a second electrode (e.g., a cathode electrode). The first electrode of the light emitting element LE may be connected to the pixel circuit PC. The second electrode of the light emitting element LE may receive the second power voltage ELVSS. For example, the second electrode of the light emitting element LE may be connected to a second power voltage line that transmits the second power voltage ELVSS.

The pixel circuit PC may include a first transistor T1, a second transistor T2, a third transistor T3, a fourth transistor T4, a fifth transistor T5, a sixth transistor T6, a seventh transistor T7, an eighth transistor T8, and a storage capacitor CST.

The first transistor T1 may include a first gate electrode G1, a first source electrode S1, and a first drain electrode D1. The first gate electrode G1 may be connected to a first node N1. The first source electrode S1 may be connected to a second node N2. The first drain electrode D1 may be connected to a third node N3. The first transistor T1 may generate the driving current DC based on a voltage between the second node N2 and the first node N1.

The second transistor T2 may include a second gate electrode G2, a second source electrode S2, and a second drain electrode D2. The second gate electrode G2 may receive the first gate signal GW. For example, the second gate electrode G2 may be connected to the first gate line GWL that transmits the first gate signal GW. The second source electrode S2 may receive the data voltage DATA. For example, the second source electrode S2 may be connected to the data line DL that transmits the data voltage DATA. The second drain electrode D2 may be connected to the second node N2. The second transistor T2 may apply the data voltage DATA to the second node N2 in response to the first gate signal GW.

The third transistor T3 may include a first sub-transistor T3-1 and a second sub-transistor T3-2. The first sub-transistor T3-1 and the second sub-transistor T3-2 may be connected in series, and the third transistor T3 may have a dual-gate structure including two gate electrodes.

The first sub-transistor T3-1 may include a first sub-gate electrode G3-1, a first sub-source electrode S3-1, and a first sub-drain electrode D3-1. The second sub-transistor T3-2 may include a second sub-gate electrode G3-2, a second sub-source electrode S3-2, and a second sub-drain electrode D3-2. Each of the first and second sub-gate electrodes G3-1 and G3-2 may receive the first gate signal GW. For example, each of the first and second sub-gate electrodes G3-1 and G3-2 may be connected to the first gate line GWL that transmits the first gate signal GW. The first sub-source electrode S3-1 may be connected to a fourth node N4. The first sub-drain electrode D3-1 may be connected to the first node N1. The second sub-source electrode S3-2 may be connected to the third node N3. The second sub-drain electrode D3-2 may be connected to the fourth node N4.

The third transistor T3 may diode-connect the first drain electrode D1 and the first gate electrode G1 of the first transistor T1 in response to the first gate signal GW.

The fourth transistor T4 may include a third sub-transistor T4-1 and a fourth sub-transistor T4-2. The third sub-transistor T4-1 and the fourth sub-transistor T4-2 may be connected in series, and the fourth transistor T4 may have a dual-gate structure including two gate electrodes.

The third sub-transistor T4-1 may include a third sub-gate electrode G4-1, a third sub-source electrode S4-1, and a third sub-drain electrode D4-1. The fourth sub-transistor T4-2 may include a fourth sub-gate electrode G4-2, a fourth sub-source electrode S4-2, and a fourth sub-drain electrode D4-2. Each of the third and fourth sub-gate electrodes G4-1 and G4-2 may receive the second gate signal GI. For example, each of the third and fourth sub-gate electrodes G4-1 and G4-2 may be connected to the second gate line GIL that transmits the second gate signal GI. The third sub-source electrode S4-1 may be connected to a fifth node N5. The third sub-drain electrode D4-1 may be connected to the first node N1. The fourth sub-source electrode S4-2 may receive the first initialization voltage VINT1. For example, the fourth sub-source electrode S4-2 may be connected to a first initialization voltage line that transmits the first initialization voltage VINT1. The fourth sub-drain electrode D4-2 may be connected to the fifth node N5.

The fourth transistor T4 may initialize the first gate electrode G1 of the first transistor T1 with the first initialization voltage VINT1 in response to the second gate signal GI.

The fifth transistor T5 may include a fifth gate electrode G5, a fifth source electrode S5, and a fifth drain electrode D5. The fifth gate electrode G5 may receive the light emitting signal EM. For example, the fifth gate electrode G5 may be connected to the light emitting line EML that transmits the light emitting signal EM. The fifth source electrode S5 may receive the first power voltage ELVDD. For example, the fifth source electrode S5 may be connected to a first power voltage line ELVDDL that transmits the first power voltage ELVDD. In an embodiment, the first power voltage ELVDD may be relatively higher than the second power voltage ELVSS. The fifth drain electrode D5 may be connected to the second node N2. The fifth transistor T5 may electrically connect the first power voltage line ELVDDL and the second node N2 in response to the light emitting signal EM.

The sixth transistor T6 may include a sixth gate electrode G6, a sixth source electrode S6, and a sixth drain electrode D6. The sixth gate electrode G6 may receive the light emitting signal EM. For example, the sixth gate electrode G6 may be connected to the light emitting line EML that transmits the light emitting signal EM. The sixth source electrode S6 may be connected to the third node N3. The sixth drain electrode D6 may be connected to a sixth node N6. The sixth transistor T6 may electrically connect the third node N3 and the light emitting element LE in response to the light emitting signal EM.

The seventh transistor T7 may include a seventh gate electrode G7, a seventh source electrode S7, and a seventh drain electrode D7. The seventh gate electrode G7 may receive the third gate signal GB. For example, the seventh gate electrode G7 may be connected to the third gate line GBL that transmits the third gate signal GB. The seventh source electrode S7 may receive the second initialization voltage VINT2. For example, the seventh source electrode S7 may be connected to a second initialization voltage line that transmits the second initialization voltage VINT2. The seventh drain electrode D7 may be connected to the sixth node N6. The seventh transistor T7 may initialize the first electrode of the light emitting element LE with the second initialization voltage VINT2 in response to the third gate signal GB.

The eighth transistor T8 may include an eighth gate electrode G8, an eighth source electrode S8, and an eighth drain electrode D8. The eighth gate electrode G8 may receive the third gate signal GB. For example, the eighth gate electrode G8 may be connected to the third gate line GBL that transmits the third gate signal GB. The eighth source electrode S8 may receive a bias voltage VBIAS. For example, the eighth source electrode S8 may be connected to a bias voltage line VBIASL that transmits the bias voltage VBIAS. The eighth drain electrode D8 may be connected to the second node N2. The eighth transistor T8 may on-bias the first transistor T1 with the bias voltage VBIAS in response to the third gate signal GB.

In an embodiment, each of the transistors T1, T2, T3, T4, T5, T6, T7, and T8 may be a P-type transistor (e.g., a PMOS transistor). In another embodiment, at least one of the transistors T1, T2, T3, T4, T5, T6, T7, and T8 may be an N-type transistor (e.g., an NMOS transistor).

The storage capacitor CST may include a first electrode and a second electrode. The first electrode may be connected to the first node N1. The second electrode may receive the first power voltage ELVDD. For example, the second electrode may be connected to the first power voltage line ELVDDL that transmits the first power voltage ELVDD. The storage capacitor CST may store a voltage of the first gate electrode G1 of the first transistor T1.

Although FIG. 3 illustrates that the pixel PX includes eight transistors T1, T2, T3, T4, T5, T6, T7, and T8 and one storage capacitor CST, the configuration of the present disclosure is not limited thereto. For example, the pixel PX may include at least one transistor and at least one storage capacitor.

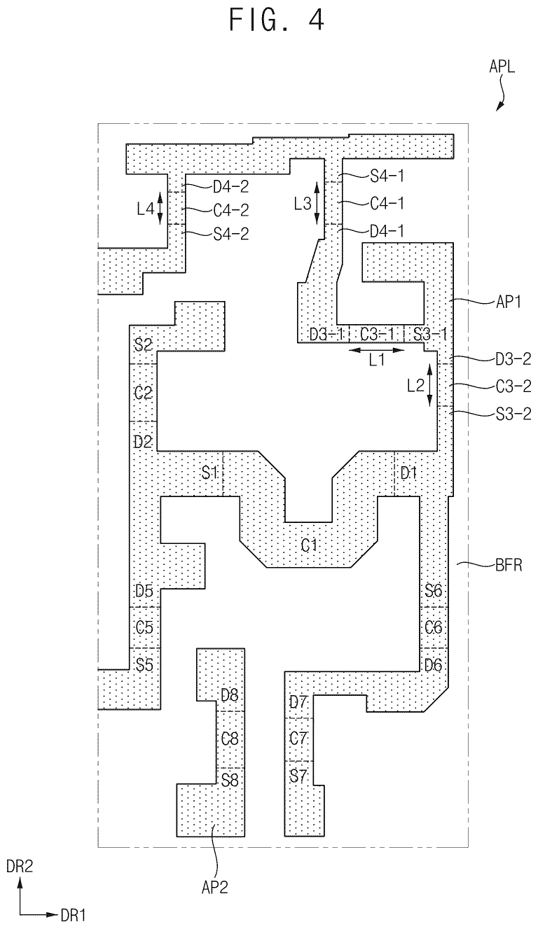

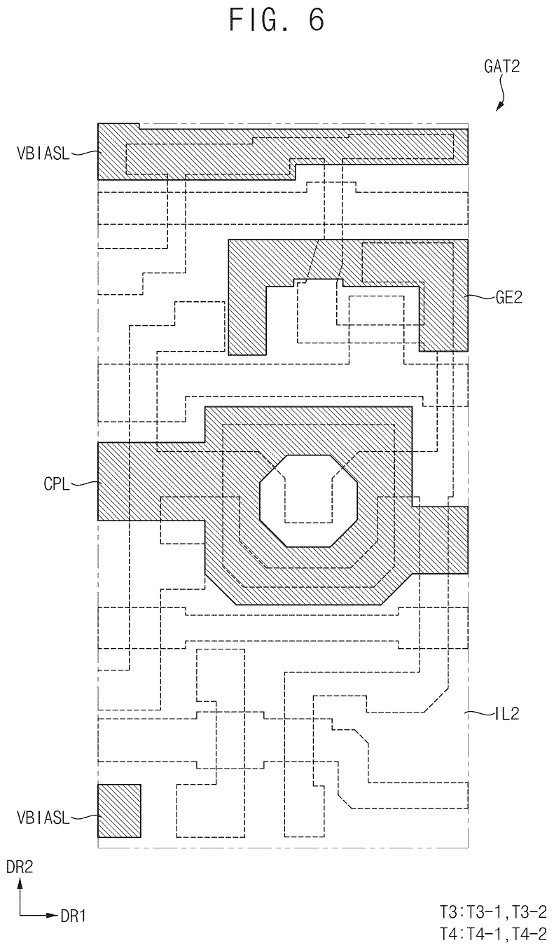

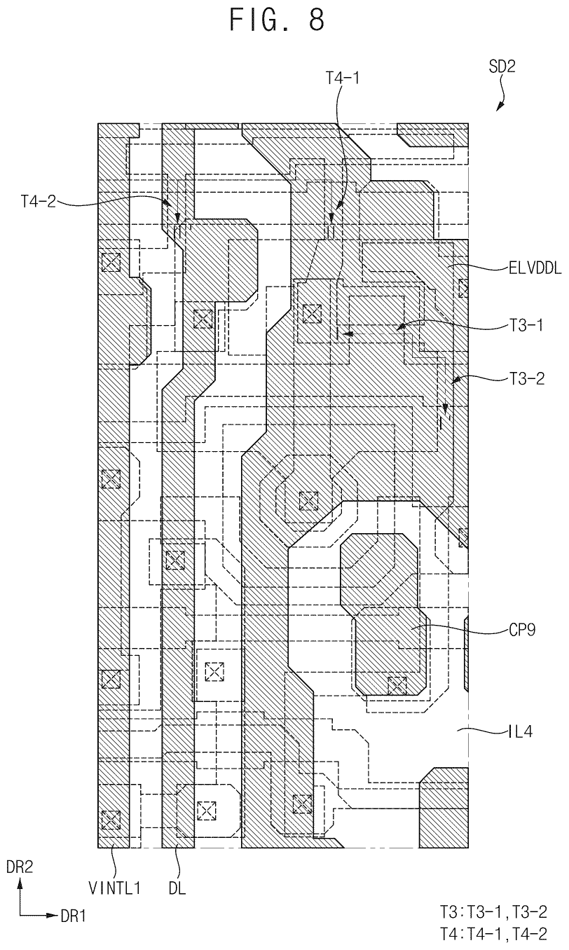

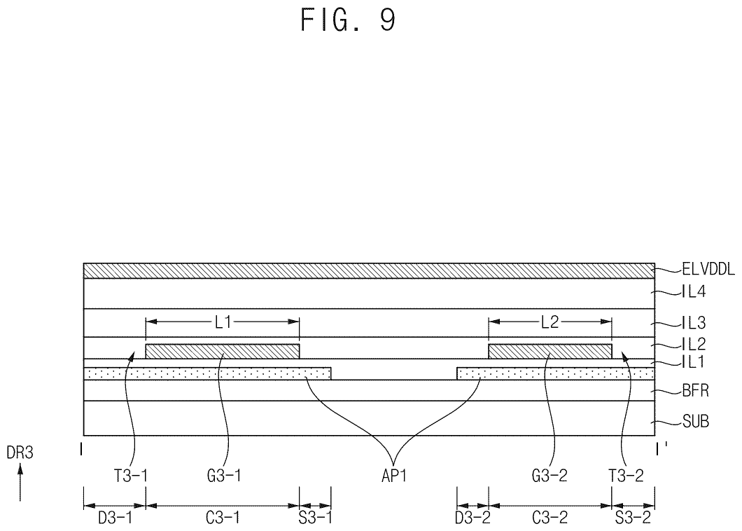

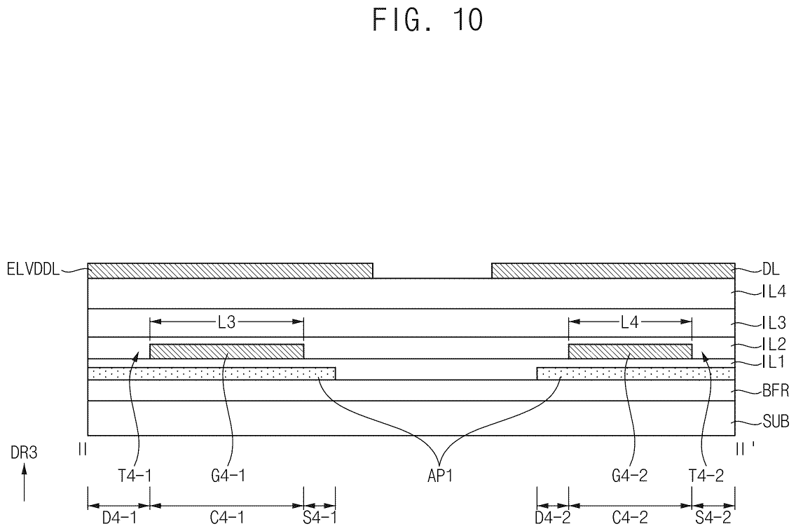

FIGS. 4, 5, 6, 7, 8, 9, 10, and 11 are diagrams illustrating a pixel included in the display device of FIG. 1. For example, FIGS. 4, 5, 6, 7, 8, and 11 may be layout diagrams (plan view) illustrating the pixel PX, FIG. 9 may be a cross-sectional view taken along line I-I′ of FIG. 8, and FIG. 10 may be a cross-sectional view taken along line II-II′ of FIG. 8. As used herein, the “plan view” is a view in a thickness direction (i.e., third direction DR3) of the substrate SUB. The third direction DR3 are perpendicular to the first direction DR1 and the second direction DR2.

Hereinafter, with reference to FIGS. 4, 5, 6, 7, 8, 9, 10, and 11, a layer-by-layer structure of the pixel PX included in the display device 10 will be described in detail.

Referring to FIGS. 3, 4, 9, and 10, a buffer layer BFR may be disposed on a substrate SUB, and an active layer APL may be disposed on the buffer layer BFR.

The substrate SUB may include a transparent material or an opaque material. For example, the substrate SUB may include a glass substrate (e.g., a rigid glass substrate), a polymer substrate, a flexible film, a metal substrate, or the like. These may be used alone or in combination with each other.

The buffer layer BFR may prevent metal atoms or impurities from being diffused from the substrate SUB. In addition, the buffer layer BFR may improve a flatness of a surface of the substrate SUB when the surface of the substrate SUB is not uniform. The buffer layer BFR may include an inorganic material such as silicon oxide (SiOₓ), silicon nitride (SiNₓ), or the like. These may be used alone or in combination with each other.

The active layer APL may include a first active pattern AP1 and a second active pattern AP2. The first active pattern AP1 may include the first source electrode S1, the first drain electrode D1, a first channel area C1, the second source electrode S2, the second drain electrode D2, a second channel area C2, the first sub-source electrode S3-1, the first sub-drain electrode D3-1, a first sub-channel area C3-1, the second sub-source electrode S3-2, the second sub-drain electrode D3-2, a second sub-channel area C3-2, the third sub-source electrode S4-1, the third sub-drain electrode D4-1, a third sub-channel area C4-1, the fourth sub-source electrode S4-2, the fourth sub-drain electrode D4-2, a fourth sub-channel area C4-2, the fifth source electrode S5, the fifth drain electrode D5, a fifth channel area C5, the sixth source electrode S6, the sixth drain electrode D6, a sixth channel area C6, the seventh source electrode S7, the seventh drain electrode D7, and a seventh channel area C7. The second active pattern AP2 may include the eighth source electrode S8, the eighth drain electrode D8, and an eighth channel area C8.

The first and second source electrodes S1 and S2, the first and second drain electrodes D1 and D2, the first, second, third, and fourth sub-source electrodes S3-1, S3-2, S4-1, and S4-2, the first, second, third, and fourth sub-drain electrodes D3-1, D3-2, D4-1, and D4-2, the fifth, sixth, seventh, and eighth source electrodes S5, S6, S7, and S8, and the fifth, sixth, seventh, and eighth drain electrodes D5, D6, D7, and D8 may be doped with impurities.

For example, the first and second source electrodes S1 and S2, the first and second drain electrodes D1 and D2, the first, second, third, and fourth sub-source electrodes S3-1, S3-2, S4-1, and S4-2, the first, second, third, and fourth sub-drain electrodes D3-1, D3-2, D4-1, and D4-2, the fifth, sixth, and seventh source electrodes S5, S6, and S7 and the fifth, sixth, and seventh drain electrodes D5, D6, and D7 may be first and second source areas, first and second drain areas, first, second, third, and fourth sub-source areas, first, second, third, and fourth sub-drain areas, fifth, sixth, and seventh source areas, and fifth, sixth, and seventh drain areas doped with impurities in the first active pattern AP1, respectively. The eighth source electrode S8 and the eighth drain electrode D8 may be an eighth source area and an eighth drain area doped with impurities in the second active pattern AP2, respectively.

The first and second channel areas C1 and C2, the first, second, third, and fourth sub-channel areas C3-1, C3-2, C4-1, and C4-2, and the fifth, sixth, seventh, and eighth channel areas C5, C6, C7, and C8 may not be doped with impurities.

The active layer APL may include a silicon semiconductor material or an oxide semiconductor material. Examples of the silicon semiconductor material may include amorphous silicon, polycrystalline silicon, or the like. Examples of the oxide semiconductor material may include indium gallium zinc oxide (IGZO), indium tin zinc oxide (ITZO), or the like. These may be used alone or in combination with each other.

Referring to FIGS. 1, 3, 4, 5, 9, and 10, a first insulating layer IL1 may be disposed on the buffer layer BFR and the active layer APL, and a first gate layer GAT1 may be disposed on the first insulating layer IL1.

In an embodiment, the first insulating layer IL1 may sufficiently cover the active layer APL, and may have a substantially flat upper surface without creating a step difference around the active layer APL. In another embodiment, the first insulating layer IL1 may cover the active layer APL, and may be disposed along a profile of the active layer APL with a uniform thickness. The first insulating layer IL1 may include an inorganic material such as silicon oxide, silicon nitride, or the like. These may be used alone or in combination with each other.

The first gate layer GAT1 may include a first gate pattern GE1, the first gate line GWL, the second gate line GIL, the light emitting line EML, and the third gate line GBL.

The first gate pattern GE1 may include the first gate electrode G1. The first gate electrode G1 may overlap the first channel area C1 in a plan view. The first source electrode S1, the first drain electrode D1, the first channel area C1, and the first gate electrode G1 may define the first transistor T1.

The first gate line GWL may extend in the first direction DR1. The first gate line GWL may transmit the first gate signal GW. The first gate line GWL may include the second gate electrode G2, the first sub-gate electrode G3-1, and the second sub-gate electrode G3-2. The first sub-gate electrode G3-1 and the second sub-gate electrode G3-2 may be spaced apart from each other. The second gate electrode G2, the first sub-gate electrode G3-1, and the second sub-gate electrode G3-2 may overlap the second channel area C2, the first sub-channel area C3-1, and the second sub-channel area C3-2, respectively, in a plan view.

The second source electrode S2, the second drain electrode D2, the second channel area C2, and the second gate electrode G2 may define the second transistor T2. The first sub-source electrode S3-1, the first sub-drain electrode D3-1, the first sub-channel area C3-1, and the first sub-gate electrode G3-1 may define the first sub-transistor T3-1. The second sub-source electrode S3-2, the second sub-drain electrode D3-2, the second sub-channel area C3-2, and the second sub-gate electrode G3-2 may define the second sub-transistor T3-2.

The first gate line GWL may include a first line portion GWL1 extending in the first direction DR1 and a first protrusion portion GWL2 protruding in the second direction DR2 from the first line portion GWL1. In an embodiment, the first sub-gate electrode G3-1 may be a portion of the first protrusion portion GWL2, and the second sub-gate electrode G3-2 may be a portion of the first line portion GWL1.

In an embodiment, a first length L1 of the first sub-gate electrode G3-1 in the first direction DR1 may be longer than a second length L2 of the second sub-gate electrode G3-2 in the second direction DR2. For example, an area A1 of the first sub-gate electrode G3-1 overlapping the first active pattern AP1 in a plan view may be greater than an area A2 of the second sub-gate electrode G3-2 overlapping the first active pattern AP1 in the plan view. The area A1 may correspond to an area of each of the first sub-channel area C3-1 and the first sub-gate electrode G3-1 in a plan view, and the area A2 may correspond to an area of each of the second sub-channel area C3-2 and the second sub-gate electrode G3-2 in a plan view. For example, a length of the first sub-gate electrode G3-1 in the second direction DR2 overlapping the first active pattern AP1 in the plan view may be substantially the same as a length of the second sub-gate electrode G3-2 in the first direction DR1 overlapping the first active pattern AP1 in the plan view.

For example, the first length L1 in the first direction DR1 and the length in the second direction DR2 of the first sub-gate electrode G3-1 may be about 4.5 micrometers (μm) and about 1.5 μm, respectively, and the length in the first direction DR1 and the second length L2 in the second direction DR2 of the second sub-gate electrode G3-2 may be about 1.5 μm and about 3.5 μm, respectively, but the present disclosure is not limited thereto.

In other words, a first length L1 of the first sub-channel area C3-1 in the first direction DR1 may be longer than a second length L2 of the second sub-channel area C3-2 in the second direction DR2. In other words, a first length L1 of the first protrusion portion GWL2 in the first direction DR1 may be longer than a second length L2 of the first line portion GWL1 in the second direction DR2.

The second gate line GIL may extend in the first direction DR1. The second gate line GIL may transmit the second gate signal GI. The second gate line GIL may include the third sub-gate electrode G4-1 and the fourth sub-gate electrode G4-2. The third sub-gate electrode G4-1 and the fourth sub-gate electrode G4-2 may be spaced apart from each other. The third sub-gate electrode G4-1 and the fourth sub-gate electrode G4-2 may overlap the third sub-channel area C4-1 and the fourth sub-channel area C4-2, respectively, in a plan view.

The third sub-source electrode S4-1, the third sub-drain electrode D4-1, the third sub-channel area C4-1, and the third sub-gate electrode G4-1 may define the third sub-transistor T4-1. The fourth sub-source electrode S4-2, the fourth sub-drain electrode D4-2, the fourth sub-channel area C4-2, and the fourth sub-gate electrode G4-2 may define the fourth sub-transistor T4-2.

The second gate line GIL may include a second line portion GIL1 extending in the first direction DR1 and a second protrusion portion GIL2 protruding in the second direction DR2 from the second line portion GIL1. In an embodiment, the third sub-gate electrode G4-1 may be a portion of the second protrusion portion GIL2 and the second line portion GIL1, and the fourth sub-gate electrode G4-2 may be a portion of the second line portion GIL1.

In an embodiment, a third length L3 of the third sub-gate electrode G4-1 in the second direction DR2 may be longer than a fourth length L4 of the fourth sub-gate electrode G4-2 in the second direction DR2. For example, an area A3 of the third sub-gate electrode G4-1 overlapping the first active pattern AP1 in the plan view may be greater than an area A4 of the fourth sub-gate electrode G4-2 overlapping the first active pattern AP1 in the plan view. The area A3 may correspond to an area of each of the third sub-channel area C4-1 and the third sub-gate electrode G4-1 in a plan view, and the area A4 may correspond to an area of each of the fourth sub-channel area C4-2 and the fourth sub-gate electrode G4-2 in a plan view. For example, a length of the third sub-gate electrode G4-1 in the first direction DR1 overlapping the first active pattern AP1 in the plan view may be substantially the same as a length of the fourth sub-gate electrode G4-2 in the first direction DR1 overlapping the first active pattern AP1 in the plan view.

For example, the length in the first direction DR1 and the third length L3 in the second direction DR2 of the third sub-gate electrode G4-1 may be about 1.5 μm and about 3.5 μm, respectively, and the length in the first direction DR1 and the fourth length L4 in the second direction DR2 of the fourth sub-gate electrode G4-2 may be about 1.5 μm and about 2.5 μm, respectively, but the present disclosure is not limited thereto.

In other words, a third length L3 of the third sub-channel area C4-1 in the second direction DR2 may be longer than a fourth length L4 of the fourth sub-channel area C4-2 in the second direction DR2. In other words, a third length L3 of the second protrusion portion GIL2 and the second line portion GIL1 in the second direction DR2 may be longer than a fourth length L4 of the second line portion GIL1 in the second direction DR2.

In an embodiment, the display panel PNL may be driven at a variable frequency. When the display panel PNL operates in a low frequency driving mode, leakage current may occur in the third transistor T3 or the fourth transistor T4, and thus luminance of the display panel PNL may be undesirably reduced. After the luminance of the display panel PNL is reduced, when the data voltage DATA is applied to the pixel PX, the luminance of the display panel PNL may be brightened and may be visually recognized as a flicker.

In particular, when voltage of the fourth node N4 of FIG. 3 varies, voltage of the first node N1 may vary, and an undesired luminance change may occur. Specifically, when the first gate signal GW rises or falls, the voltage of the fourth node N4 may rise or fall together. In this case, leakage current may occur in the third transistor T3 due to a difference between the voltage of the first node N1 and the voltage of the fourth node N4, and an undesired luminance change may occur as the voltage of the first node N1 varies.

In addition, when voltage of the fifth node N5 of FIG. 3 varies, the voltage of the first node N1 may vary, and an undesired luminance change may occur. Specifically, when the second gate signal GI rises or falls, the voltage of the fifth node N5 may rise or fall together. In this case, leakage current may occur in the fourth transistor T4 due to a difference between the voltage of the first node N1 and the voltage of the fifth node N5, and an undesired luminance change may occur as the voltage of the first node N1 varies.

In this case, in a transistor having a dual-gate structure, when a sub-transistor including a channel area of a relatively large area is used as a drain transistor, leakage current of the transistor may be reduced.

That is, in an embodiment, in the third transistor T3, as the first length L1 of the first sub-gate electrode G3-1 (or the first sub-channel area C3-1) of the first sub-transistor T3-1 may be relatively longer than the second length L2 of the second sub-gate electrode G3-2 (or the second sub-channel area C3-2) of the second sub-transistor T3-2, and the first sub-transistor T3-1 may be used as a drain transistor, leakage current that flows through the third transistor T3 may be reduced. For example, leakage current that flows from the third transistor T3 to the first node N1 may be reduced. Accordingly, voltage of the first gate electrode G1 of the first transistor T1 may be stabilized, and deterioration of display quality due to the leakage current may be minimized.

In addition, in an embodiment, in the fourth transistor T4, as the third length L3 of the third sub-gate electrode G4-1 (or the third sub-channel area C4-1) of the third sub-transistor T4-1 may be relatively longer than the fourth length L4 of the fourth sub-gate electrode G4-2 (or the fourth sub-channel area C4-2) of the fourth sub-transistor T4-2, and the third sub-transistor T4-1 may be used as a drain transistor, leakage current that flows through the fourth transistor T4 may be reduced. For example, a compensation current for a leakage current that flows from the fourth transistor T4 to the first node N1 may be generated, and the leakage current may be reduced. Accordingly, the voltage of the first gate electrode G1 of the first transistor T1 may be stabilized, and deterioration of display quality due to the leakage current may be minimized.

The light emitting line EML may extend in the first direction DR1. The light emitting line EML may transmit the light emitting signal EM. The light emitting line EML may include the fifth gate electrode G5 and the sixth gate electrode G6. The fifth gate electrode G5 and the sixth gate electrode G6 may overlap the fifth channel area C5 and the sixth channel area C6, respectively, in a plan view.

The fifth source electrode S5, the fifth drain electrode D5, the fifth channel area C5, and the fifth gate electrode G5 may define the fifth transistor T5. The sixth source electrode S6, the sixth drain electrode D6, the sixth channel area C6, and the sixth gate electrode G6 may define the sixth transistor T6.

The third gate line GBL may extend in the first direction DR1. The third gate line GBL may transmit the third gate signal GB. The third gate line GBL may include the seventh gate electrode G7 and the eighth gate electrode G8. The seventh gate electrode G7 and the eighth gate electrode G8 may overlap the seventh channel area C7 and the eighth channel area C8, respectively, in a plan view.

The seventh source electrode S7, the seventh drain electrode D7, the seventh channel area C7, and the seventh gate electrode G7 may define the seventh transistor T7. The eighth source electrode S8, the eighth drain electrode D8, the eighth channel area C8, and the eighth gate electrode G8 may define the eighth transistor T8.

The first gate layer GAT1 may include a conductive material such as a metal, an alloy, a conductive metal oxide, a transparent conductive material, or the like. These may be used alone or in combination with each other. The first gate layer GAT1 may be formed of a single layer or multiple layers.

Referring to FIGS. 3, 5, and 6, a second insulating layer IL2 may be disposed on the first insulating layer IL1 and the first gate layer GAT1, and a second gate layer GAT2 may be disposed on the second insulating layer IL2.

In an embodiment, the second insulating layer IL2 may sufficiently cover the first gate layer GAT1, and may have a substantially flat upper surface without creating a step difference around the first gate layer GAT1. In another embodiment, the second insulating layer IL2 may cover the first gate layer GAT1, and may be disposed along a profile of the first gate layer GAT1 with a uniform thickness. The second insulating layer IL2 may include an inorganic material such as silicon oxide, silicon nitride, or the like. These may be used alone or in combination with each other.

The second gate layer GAT2 may include a capacitor line CPL, a second gate pattern GE2, and a bias voltage line VBIASL.

The capacitor line CPL may extend in the first direction DR1. The capacitor line CPL may overlap the first gate pattern GE1 in a plan view. For example, the capacitor line CPL may define the storage capacitor CST together with the first gate pattern GEL.

The second gate pattern GE2 may overlap the first active pattern AP1 in a plan view. For example, the second gate pattern GE2 may define a capacitor together with the first active pattern APL. The capacitor may include a first electrode connected to the fourth node N4 and a second electrode that receives the first power voltage ELVDD. As the capacitor may be connected to the fourth node N4, a voltage difference between the first node N1 and the fourth node N4 may be reduced. Accordingly, leakage current that flows through the third transistor T3 may be reduced.

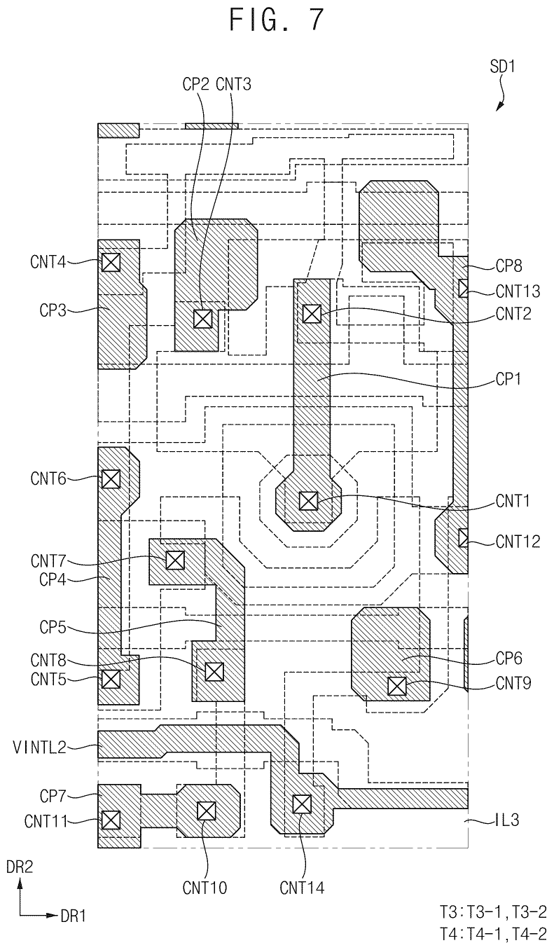

In addition, the second gate pattern GE2 may prevent a coupling phenomenon that may occur between electrodes included in a layer disposed on the second gate layer GAT2. For example, the second gate pattern GE2 may prevent a coupling phenomenon that may occur between connection patterns (e.g., a first connection pattern CP1 and a second connection pattern CP2 of FIG. 7) included in a conductive layer (e.g., a first conductive layer SD1 of FIG. 7) disposed on the second gate layer GAT2.

The bias voltage line VBIASL may extend in the first direction DR1. The bias voltage line VBIASL may transmit the bias voltage VBIAS.

The second gate layer GAT2 may include a conductive material such as a metal, an alloy, a conductive metal oxide, a transparent conductive material, or the like. These may be used alone or in combination with each other. The second gate layer GAT2 may be formed of a single layer or multiple layers.

Referring to FIGS. 4, 5, 6, and 7, a third insulating layer IL3 may be disposed on the second insulating layer IL2 and the second gate layer GAT2, and a first conductive layer SD1 may be disposed on the third insulating layer IL3.

In an embodiment, the third insulating layer IL3 may sufficiently cover the second gate layer GAT2, and may have a substantially flat upper surface without creating a step difference around the second gate layer GAT2. In another embodiment, the third insulating layer IL3 may cover the second gate layer GAT2, and may be disposed along a profile of the second gate layer GAT2 with a uniform thickness. The third insulating layer IL3 may include an inorganic material such as silicon oxide, silicon nitride, or the like. These may be used alone or in combination with each other.

The first conductive layer SD1 may include a first connection pattern CP1, a second connection pattern CP2, a third connection pattern CP3, a fourth connection pattern CP4, a fifth connection pattern CP5, a sixth connection pattern CP6, a seventh connection pattern CP7, an eighth connection pattern CP8, and a second initialization voltage line VINTL2.

The first connection pattern CP1 may connect the first gate pattern GE1 to the first sub-drain electrode D3-1 and the third sub-drain electrode D4-1. For example, the first connection pattern CP1 may be electrically connected to the first gate pattern GE1 through a first contact hole CNT1, and may be electrically connected to the first sub-drain electrode D3-1 and the third sub-drain electrode D4-1 through a second contact hole CNT2.

The second connection pattern CP2 may be connected to the second source electrode S2. For example, the second connection pattern CP2 may be electrically connected to the second source electrode S2 through a third contact hole CNT3.

The third connection pattern CP3 may be connected to the fourth sub-source electrode S4-2. For example, the third connection pattern CP3 may be electrically connected to the fourth sub-source electrode S4-2 through a fourth contact hole CNT4.

The fourth connection pattern CP4 may connect the fifth source electrode S5 to the capacitor line CPL. For example, the fourth connection pattern CP4 may be electrically connected to the fifth source electrode S5 through a fifth contact hole CNT5, and may be electrically connected to the capacitor line CPL through a sixth contact hole CNT6.

The fifth connection pattern CP5 may connect the first source electrode S1, the second drain electrode D2, and the fifth drain electrode D5 to the eighth drain electrode D8. For example, the fifth connection pattern CP5 may be electrically connected to the first source electrode S1, the second drain electrode D2, and the fifth drain electrode D5 through a seventh contact hole CNT7, and may be electrically connected to the eighth drain electrode D8 through an eighth contact hole CNT8.

The sixth connection pattern CP6 may be connected to the sixth drain electrode D6 and the seventh drain electrode D7. For example, the sixth connection pattern CP6 may be electrically connected to the sixth drain electrode D6 and the seventh drain electrode D7 through a ninth contact hole CNT9.

The seventh connection pattern CP7 may connect the eighth source electrode S8 to the bias voltage line VBIASL. For example, the seventh connection pattern CP7 may be electrically connected to the eighth source electrode S8 through a tenth contact hole CNT10, and may be electrically connected to the bias voltage line VBIASL through an eleventh contact hole CNT11.

The eighth connection pattern CP8 may connect the capacitor line CPL to the second gate pattern GE2. For example, the eighth connection pattern CP8 may be electrically connected to the capacitor line CPL through a twelfth contact hole CNT12, and may be electrically connected to the second gate pattern GE2 through a thirteenth contact hole CNT13.

The second initialization voltage line VINTL2 may transmit the second initialization voltage VINTL2. The second initialization voltage line VINTL2 may be connected to the seventh source electrode S7. For example, the second initialization voltage line VINT2 may be electrically connected to the seventh source electrode S7 through a fourteenth contact hole CNT14.

The first conductive layer SD1 may include a conductive material such as a metal, an alloy, a conductive metal oxide, a transparent conductive material, or the like. These may be used alone or in combination with each other. The first conductive layer SD1 may be formed of a single layer or multiple layers.

Referring to FIGS. 7, 8, 9, and 10, a fourth insulating layer IL4 may be disposed on the third insulating layer IL3 and the first conductive layer SD1, and a second conductive layer SD2 may be disposed on the fourth insulating layer IL4.

In an embodiment, the fourth insulating layer IL4 may sufficiently cover the first conductive layer SD1, and may have a substantially flat upper surface without creating a step difference around the first conductive layer SD1. In another embodiment, the fourth insulating layer IL4 may cover the first conductive layer SD1, and may be disposed along a profile of the first conductive layer SD1 with a uniform thickness. The fourth insulating layer IL4 may include an inorganic material such as silicon oxide, silicon nitride, or the like. These may be used alone or in combination with each other.

The second conductive layer SD2 may include a ninth connection pattern CP9, a first power voltage line ELVDDL, the data line DL, and a first initialization voltage line VINTL1.

In an embodiment, the second conductive layer SD2 may overlap at least a portion of the third transistor T3 or the fourth transistor T4 in a plan view. That is, the second conductive layer SD2 may overlap at least a portion of the first sub-transistor T3-1, the second sub-transistor T3-2, the third sub-transistor T4-1, or the fourth sub-transistor T4-2 in a plan view. For example, the second conductive layer SD2 may overlap the first, second, third, and fourth sub-gate electrodes G3-1, G3-2, G4-1, and G4-2 and the first, second, third, and fourth sub-channel areas C3-1, C3-2, C4-1, and C4-2 in a plan view.

The first power voltage line ELVDDL may extend in the second direction DR2. The first power voltage line ELVDDL may transmit the first power voltage ELVDD.

In an embodiment, the first power voltage line ELVDDL may overlap at least a portion of the first, second, and third sub-transistors T3-1, T3-2, and T4-1 in a plan view. For example, the first power voltage line ELVDDL may overlap the first, second, and third sub-gate electrodes G3-1, G3-2, and G4-1 and the first, second, and third sub-channel areas C3-1, C3-2, and C4-1 in a plan view. That is, the first power voltage line ELVDDL may shield upper portions of the first sub-channel area C3-1 and the first sub-gate electrode G3-1 having the first length L1, the second sub-channel area C3-2 and the second sub-gate electrode G3-2 having the second length L2, and the third sub-channel area C4-1 and the third sub-gate electrode G4-1 having the third length L3. The first power voltage line ELVDDL may further overlap at least a portion of the first, second, and third sub-source electrodes S3-1, S3-2, and S4-1 and the first, second, and third sub-drain electrodes D3-1, D3-2, and D4-1 in a plan view.

The data line DL may extend in the second direction DR2. The data line DL may transmit the data voltage DATA.

In an embodiment, the data line DL may overlap the fourth sub-transistor T4-2 in a plan view. For example, the data line DL may overlap the fourth sub-gate electrode G4-2 and the fourth sub-channel area C4-2 in a plan view. That is, the data line DL may shield upper portions of the fourth sub-channel area C4-2 and the fourth sub-gate electrode G4-2 having the fourth length L4. The data line DL may further overlap at least a portion of the fourth sub-source electrode S4-2 and the fourth sub-drain electrode D4-2 in a plan view.

As the second conductive layer SD2 may shield the third transistor T3 or the fourth transistor T4, leakage current that occurs in the third transistor T3 or the fourth transistor T4 due to external light may be reduced. Accordingly, deterioration of display quality due to the leakage current may be minimized.

Although FIGS. 8, 9, and 10 illustrate that the second conductive layer SD2 overlaps the first, second, third, and fourth sub-transistors T3-1, T3-2, T4-1, and T4-2 in a plan view, the present disclosure is not limited thereto. For another example, the second conductive layer SD2 may overlap at least one of the first, second, third, and fourth sub-transistors T3-1, T3-2, T4-1, and T4-2 in a plan view.

Referring to FIGS. 3, 8, and 11, a via insulating layer VIA may be disposed on the fourth insulating layer IL4 and the second conductive layer SD2, and a pixel electrode layer PXL may be disposed on the via insulating layer VIA.

The via insulating layer VIA may sufficiently cover the second conductive layer SD2. The via insulating layer VIA may include an organic material such as phenol resin, acrylic resin, polyimide resin, polyamide resin, siloxane resin, epoxy resin, or the like. These may be used alone or in combination with each other.

The pixel electrode layer PXL may include a first pixel electrode PE1, a second pixel electrode PE2, and a third pixel electrode PE3. The first, second, and third pixel electrodes PE1, PE2, and PE3 may be spaced apart from each other. The first, second, and third pixel electrodes PE1, PE2, and PE3 may correspond to the first electrode of the light emitting element LE of FIG. 3.

In an embodiment, the pixel electrode layer PXL may overlap at least a portion of the third transistor T3 or the fourth transistor T4 in a plan view. That is, the pixel electrode layer PXL may overlap at least a portion of the first sub-transistor T3-1, the second sub-transistor T3-2, the third sub-transistor T4-1, or the fourth sub-transistor T4-2 in a plan view. For example, the pixel electrode layer PXL may overlap at least a portion of the first, second, third, and fourth sub-gate electrodes G3-1, G3-2, G4-1, and G4-2 and the first, second, third, and fourth sub-channel areas C3-1, C3-2, C4-1, and C4-2 in a plan view.

In an embodiment, the first pixel electrode PE1 may overlap at least a portion of the fourth sub-transistor T4-2 in a plan view. For example, the first pixel electrode PE1 may overlap the fourth sub-gate electrode G4-2 and the fourth sub-channel area C4-2 in a plan view. The first pixel electrode PE1 may further overlap at least a portion of the fourth sub-source electrode S4-2 and the fourth sub-drain electrode D4-2 in a plan view.

In an embodiment, the second pixel electrode PE2 may overlap at least a portion of the first and second sub-transistors T3-1 and T3-2 in a plan view. For example, the second pixel electrode PE2 may overlap at least a portion of the first and second sub-gate electrodes G3-1 and G3-2 and the first and second sub-channel areas C3-1 and C3-2 in a plan view. The second pixel electrode PE2 may further overlap at least a portion of the first and second sub-source electrodes S3-1 and S3-2 and the first and second sub-drain electrodes D3-1 and D3-2 in a plan view.

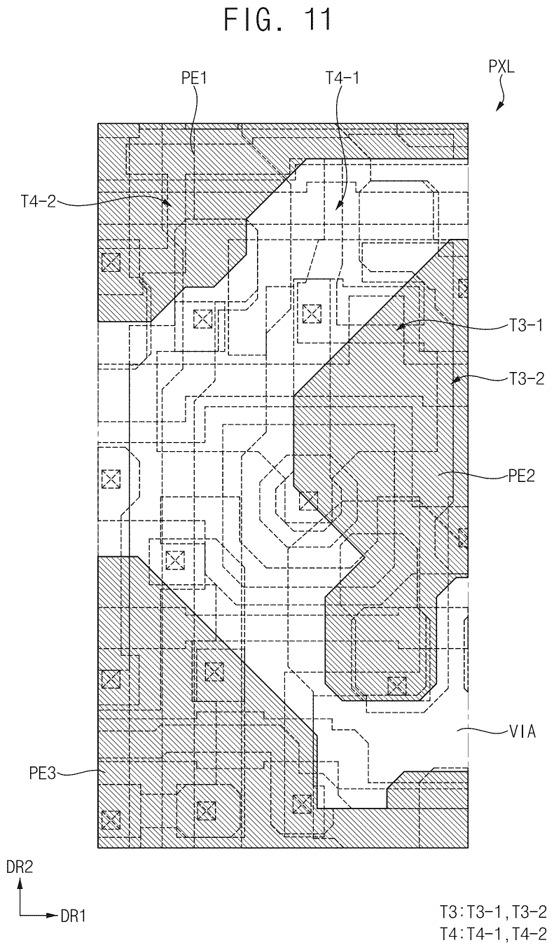

Although FIG. 11 illustrates that the pixel electrode layer PXL at least partially overlaps the first, second, and fourth sub-transistors T3-1, T3-2, and T4-2 in a plan view, the present disclosure is not limited thereto. For another example, the pixel electrode layer PXL may at least partially overlap at least one of the first, second, third, and fourth sub-transistors T3-1, T3-2, T4-1, and T4-2 in a plan view.

As the pixel electrode layer PXL may shield at least a portion of the third transistor T3 or the fourth transistor T4, leakage current that occurs in the third transistor T3 or the fourth transistor T4 due to external light may be reduced. Accordingly, deterioration of display quality due to the leakage current may be minimized.

The display device 10 according to an embodiment of the present disclosure may include the third transistor T3 including the first and second sub-transistors T3-1 and T3-2 and the fourth transistor T4 including the third and fourth sub-transistors T4-1 and T4-2. As the first sub-channel area C3-1 of the first sub-transistor T3-1 and the third sub-channel area C4-1 of the third sub-transistor T4-1 may have relatively long lengths, the leakage current that occurs in the third and fourth transistors T3 and T4 may be reduced. In addition, as the second conductive layer SD2 may shield the third and fourth transistors T3 and T4, the leakage current that occurs in the third and fourth transistors T3 and T4 due to external light may be reduced. Accordingly, deterioration of display quality due to the leakage current may be minimized, and display quality of the display device 10 may be effectively improved by displaying an image with uniform luminance.

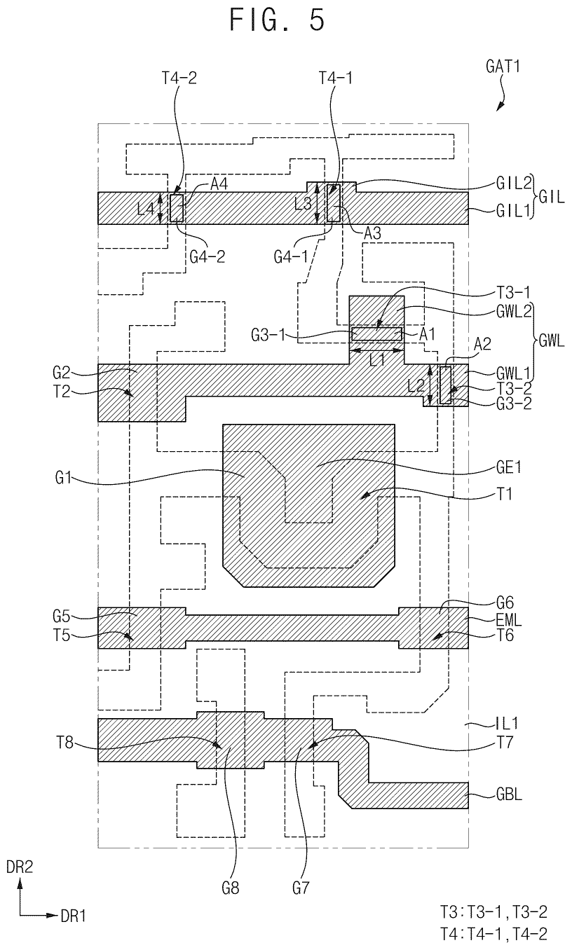

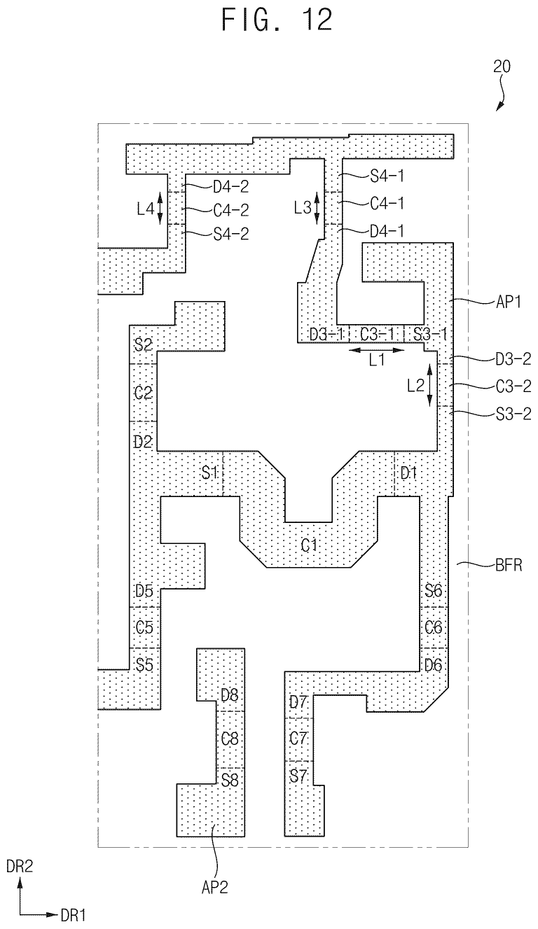

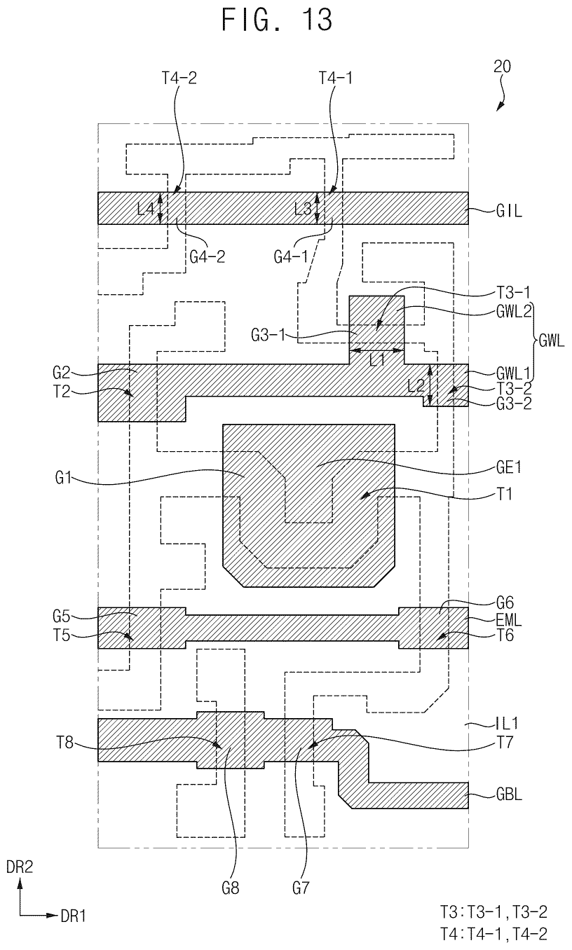

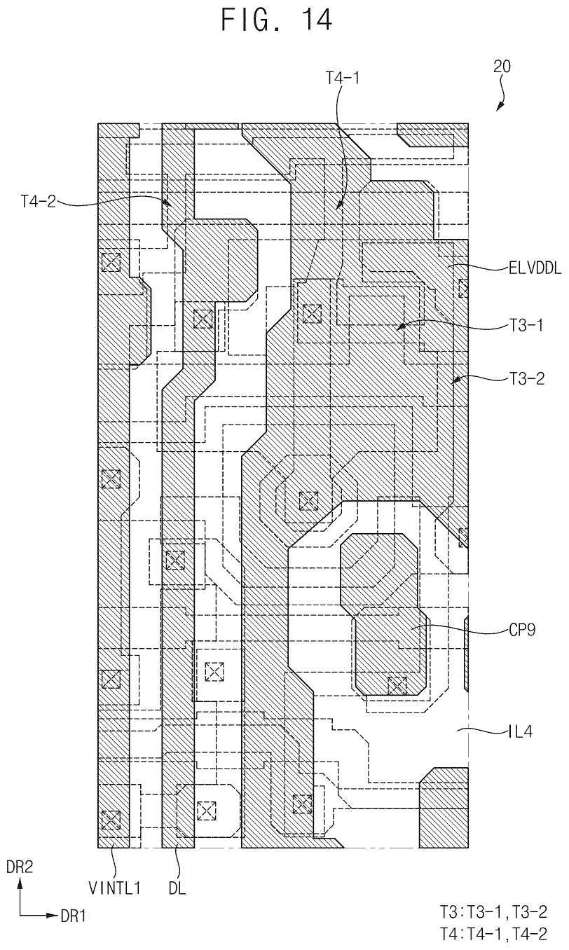

FIGS. 12, 13, and 14 are diagrams illustrating a display device according to another embodiment of the present disclosure. For example, FIG. 12 may be a layout diagram corresponding to FIG. 4, FIG. 13 may be a layout diagram corresponding to FIG. 5, and FIG. 14 may be a layout diagram corresponding to FIG. 8. That is, FIGS. 12, 13, and 14 may be layout diagrams illustrating a pixel included in a display device 20.

The display device 20 described with reference to FIGS. 12, 13, and 14 may be substantially the same as or similar to the display device 10 described with reference to FIGS. 1 to 11 except for the fourth transistor T4. Hereinafter, redundant descriptions will be omitted or simplified.

Referring to FIGS. 12, 13, and 14, an active layer APL may be disposed on a buffer layer BFR. The active layer APL may include a first active pattern AP1 and a second active pattern AP2.

The first active pattern AP1 may include a first source electrode S1, a first drain electrode D1, a first channel area C1, a second source electrode S2, a second drain electrode D2, a second channel area C2, a first sub-source electrode S3-1, a first sub-drain electrode D3-1, a first sub-channel area C3-1, a second sub-source electrode S3-2, a second sub-drain electrode D3-2, a second sub-channel area C3-2, a third sub-source electrode S4-1, a third sub-drain electrode D4-1, a third sub-channel area C4-1, a fourth sub-source electrode S4-2, a fourth sub-drain electrode D4-2, a fourth sub-channel area C4-2, a fifth source electrode S5, a fifth drain electrode D5, a fifth channel area C5, a sixth source electrode S6, a sixth drain electrode D6, a sixth channel area C6, a seventh source electrode S7, a seventh drain electrode D7, and a seventh channel area C7. The second active pattern AP2 may include an eighth source electrode S8, an eighth drain electrode D8, and an eighth channel area C8.

A first insulating layer IL1 and a first gate layer GAT1 may be sequentially disposed on the buffer layer BFR and the active layer APL. The first gate layer GAT1 may include a first gate pattern GE1, a first gate line GWL, a second gate line GIL, a light emitting line EML, and a third gate line GBL.

The first gate pattern GE1 may include a first gate electrode G1 overlapping the first channel area C1 in a plan view.

The first gate line GWL may include a second gate electrode G2 overlapping the second channel area C2 in a plan view, a first sub-gate electrode G3-1 overlapping the first sub-channel area C3-1 in a plan view, and a second sub-gate electrode G3-2 overlapping the second sub-channel area C3-2 in a plan view.

The first sub-source electrode S3-1, the first sub-drain electrode D3-1, the first sub-channel area C3-1, and the first sub-gate electrode G3-1 may define a first sub-transistor T3-1. The second sub-source electrode S3-2, the second sub-drain electrode D3-2, the second sub-channel area C3-2, and the second sub-gate electrode G3-2 may define a second sub-transistor T3-2. The first sub-transistor T3-1 and the second sub-transistor T3-2 may define a third transistor T3. That is, the third transistor T3 may have a dual-gate structure including two gate electrodes.

The first gate line GWL may include a line portion GWL1 extending in a first direction DR1 and a protrusion portion GWL2 protruding from the line portion GWL1 in a second direction DR2 intersecting the first direction DR1. The first sub-gate electrode G3-1 may be a portion of the protrusion portion GWL2, and the second sub-gate electrode G3-2 may be a portion of the line portion GWL1.

In an embodiment, a first length L1 of the first sub-gate electrode G3-1 in the first direction DR1 may be longer than a second length L2 of the second sub-gate electrode G3-2 in the second direction DR2. For example, an area of the first sub-gate electrode G3-1 overlapping the first active pattern AP1 in the plan view may be greater than an area of the second sub-gate electrode G3-2 overlapping the first active pattern AP1 in the plan view. For example, a length of the first sub-gate electrode G3-1 in the second direction DR2 overlapping the first active pattern AP1 in the plan view may be substantially the same as a length of the second sub-gate electrode G3-2 in the first direction DR1 overlapping the first active pattern AP1 in the plan view.

In other words, a first length L1 of the first sub-channel area C3-1 in the first direction DR1 may be longer than a second length L2 of the second sub-channel area C3-2 in the second direction DR2. In other words, a first length L1 of the protrusion portion GWL2 in the first direction DR1 may be longer than a second length L2 of the line portion GWL1 in the second direction DR2.

The second gate line GIL may include a third sub-gate electrode G4-1 overlapping the third sub-channel area C4-1 in a plan view and a fourth sub-gate electrode G4-2 overlapping the fourth sub-channel area C4-2 in a plan view.

The third sub-source electrode S4-1, the third sub-drain electrode D4-1, the third sub-channel area C4-1, and the third sub-gate electrode G4-1 may define a third sub-transistor T4-1. The fourth sub-source electrode S4-2, the fourth sub-drain electrode D4-2, the fourth sub-channel area C4-2, and the fourth sub-gate electrode G4-2 may define a fourth sub-transistor T4-2. The third sub-transistor T4-1 and the fourth sub-transistor T4-2 may define a fourth transistor T4. That is, the fourth transistor T4 may have a dual-gate structure including two gate electrodes.

In an embodiment, a third length L3 of the third sub-gate electrode G4-1 in the second direction DR2 may be substantially the same as a fourth length L4 of the fourth sub-gate electrode G4-2 in the second direction DR2. For example, an area of the third sub-gate electrode G4-1 overlapping the first active pattern AP1 in the plan view may be substantially the same as an area of the fourth sub-gate electrode G4-2 overlapping the first active pattern AP1 in the plan view. For example, a length of the third sub-gate electrode G4-1 in the first direction DR1 overlapping the first active pattern AP1 in the plan view may be substantially the same as a length of the fourth sub-gate electrode G4-2 in the first direction DR1 overlapping the first active pattern AP1 in the plan view. In other words, a third length L3 of the third sub-channel area C4-1 in the second direction DR2 may be substantially the same as a fourth length L4 of the fourth sub-channel area C4-2 in the second direction DR2.

The light emitting line EML may include a fifth gate electrode G5 overlapping the fifth channel area C5 in a plan view and a sixth gate electrode G6 overlapping the sixth channel area C6 in a plan view.

The third gate line GBL may include a seventh gate electrode G7 overlapping the seventh channel area C7 in a plan view and an eighth gate electrode G8 overlapping the eighth channel area C8 in a plan view.

A fourth insulating layer IL4 and a second conductive layer SD2 may be sequentially disposed on the first insulating layer IL1 and the first gate layer GAT1. The second conductive layer SD2 may include a ninth connection pattern CP9, a first power voltage line ELVDDL, a data line DL, and a first initialization voltage line VINTL1.

In an embodiment, the second conductive layer SD2 may overlap at least a portion of the first sub-transistor T3-1, the second sub-transistor T3-2, the third sub-transistor T4-1, or the fourth sub-transistor T4-2 in a plan view.

For example, the first power voltage line ELVDDL may overlap the first, second, and third sub-transistors T3-1, T3-2, and T4-1 in a plan view. For example, the first power voltage line ELVDDL may overlap the first, second, and third sub-gate electrodes G3-1, G3-2, and G4-1 and the first, second, and third sub-channel areas C3-1, C3-2, and C4-1 in a plan view, and may shield upper portions of the first, second, and third sub-gate electrodes G3-1, G3-2, and G4-1 and the first, second, and third sub-channel areas C3-1, C3-2, and C4-1.

For example, the data line DL may overlap the fourth sub-transistor T4-2 in a plan view. For example, the data line DL may overlap the fourth sub-gate electrode G4-2 and the fourth sub-channel area C4-2 in a plan view, and may shield upper portions of the fourth sub-gate electrode G4-2 and the fourth sub-channel area C4-2.

The display device 20 according to an embodiment of the present disclosure may include the third transistor T3 including the first and second sub-transistors T3-1 and T3-2 and the fourth transistor T4 including the third and fourth sub-transistors T4-1 and T4-2. As the first sub-channel area C3-1 of the first sub-transistor T3-1 may have a relatively long length, leakage current that occurs in the third transistor T3 may be reduced. In addition, as the second conductive layer SD2 may shield the third and fourth transistors T3 and T4, leakage current that occurs in the third and fourth transistors T3 and T4 due to external light may be reduced. Accordingly, deterioration of display quality due to the leakage current may be minimized, and display quality of the display device 20 may be effectively improved by displaying an image with uniform luminance.

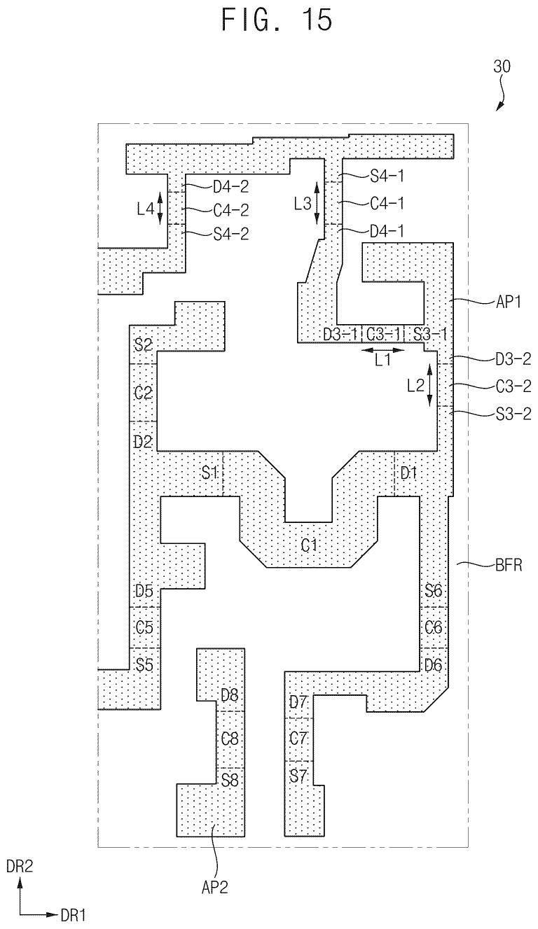

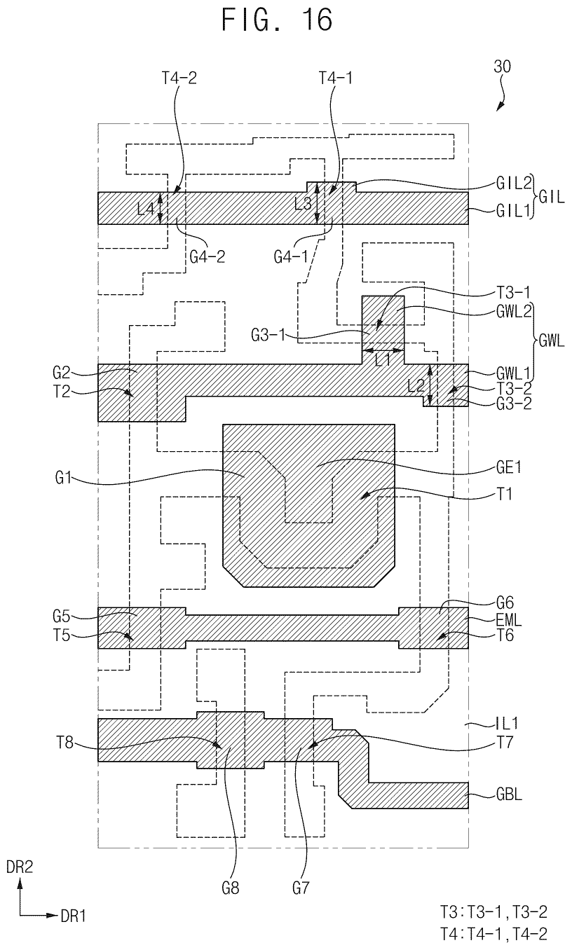

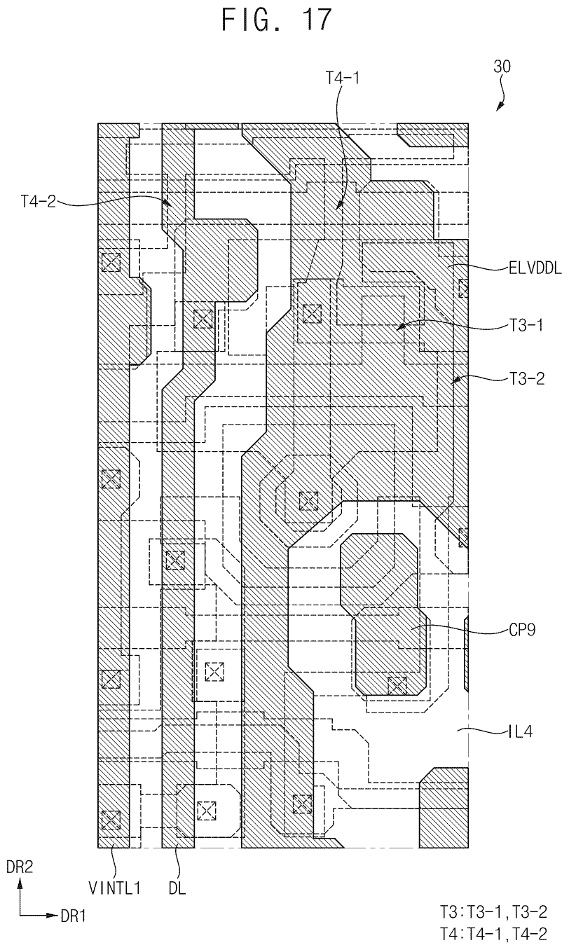

FIGS. 15, 16, and 17 are diagrams illustrating a display device according to still another embodiment of the present disclosure. For example, FIG. 15 may be a layout diagram corresponding to FIG. 4, FIG. 16 may be a layout diagram corresponding to FIG. 5, and FIG. 17 may be a layout diagram corresponding to FIG. 8. That is, FIGS. 15, 16, and 17 may be layout diagrams illustrating a pixel included in a display device 30.

The display device 30 described with reference to FIGS. 15, 16, and 17 may be substantially the same as or similar to the display device 10 described with reference to FIGS. 1 to 11, except for the third transistor T3. Hereinafter, redundant descriptions will be omitted or simplified.

Referring to FIGS. 15, 16, and 17, an active layer APL may be disposed on a buffer layer BFR. The active layer APL may include a first active pattern AP1 and a second active pattern AP2.

The first active pattern AP1 may include a first source electrode S1, a first drain electrode D1, a first channel area C1, a second source electrode S2, a second drain electrode D2, a second channel area C2, a first sub-source electrode S3-1, a first sub-drain electrode D3-1, a first sub-channel area C3-1, a second sub-source electrode S3-2, a second sub-drain electrode D3-2, a second sub-channel area C3-2, a third sub-source electrode S4-1, a third sub-drain electrode D4-1, a third sub-channel area C4-1, a fourth sub-source electrode S4-2, a fourth sub-drain electrode D4-2, a fourth sub-channel area C4-2, a fifth source electrode S5, a fifth drain electrode D5, a fifth channel area C5, a sixth source electrode S6, a sixth drain electrode D6, a sixth channel area C6, a seventh source electrode S7, a seventh drain electrode D7, and a seventh channel area C7. The second active pattern AP2 may include an eighth source electrode S8, an eighth drain electrode D8, and an eighth channel area C8.

A first insulating layer IL1 and a first gate layer GAT1 may be sequentially disposed on the buffer layer BFR and the active layer APL. The first gate layer GAT1 may include a first gate pattern GE1, a first gate line GWL, a second gate line GIL, a light emitting line EML, and a third gate line GBL.

The first gate pattern GE1 may include a first gate electrode G1 overlapping the first channel area C1 in a plan view.

The first gate line GWL may include a second gate electrode G2 overlapping the second channel area C2 in a plan view, a first sub-gate electrode G3-1 overlapping the first sub-channel area C3-1 in a plan view, and a second sub-gate electrode G3-2 overlapping the second sub-channel area C3-2 in a plan view.

The first sub-source electrode S3-1, the first sub-drain electrode D3-1, the first sub-channel area C3-1, and the first sub-gate electrode G3-1 may define a first sub-transistor T3-1. The second sub-source electrode S3-2, the second sub-drain electrode D3-2, the second sub-channel area C3-2, and the second sub-gate electrode G3-2 may define a second sub-transistor T3-2. The first sub-transistor T3-1 and the second sub-transistor T3-2 may define a third transistor T3. That is, the third transistor T3 may have a dual-gate structure including two gate electrodes.

The first gate line GWL may include a first line portion GWL1 extending in a first direction DR1 and a first protrusion portion GWL2 protruding from the first line portion GWL1 in a second direction DR2 intersecting the first direction DR1. The first sub-gate electrode G3-1 may be a portion of the first protrusion portion GWL2, and the second sub-gate electrode G3-2 may be a portion of the first line portion GWL1.

In an embodiment, a first length L1 of the first sub-gate electrode G3-1 in the first direction DR1 may be substantially the same as a second length L2 of the second sub-gate electrode G3-2 in the second direction DR2. For example, an area of the first sub-gate electrode G3-1 overlapping the first active pattern AP1 in the plan view may be substantially the same as an area of the second sub-gate electrode G3-2 overlapping the first active pattern AP1 in the plan view. For example, a length of the first sub-gate electrode G3-1 in the second direction DR2 overlapping the first active pattern AP1 in the plan view may be substantially the same as a length of the second sub-gate electrode G3-2 in the first direction DR1 overlapping the first active pattern AP1 in the plan view.

In other words, a first length L1 of the first sub-channel area C3-1 in the first direction DR1 may be substantially the same as a second length L2 of the second sub-channel area C3-2 in the second direction DR2. In other words, a first length L1 of the first protrusion portion GWL2 in the first direction DR1 may be substantially the same as a second length L2 of the first line portion GWL1 in the second direction DR2.

The second gate line GIL may include a third sub-gate electrode G4-1 overlapping the third sub-channel area C4-1 in a plan view and a fourth sub-gate electrode G4-2 overlapping the fourth sub-channel area C4-2 in a plan view.

The third sub-source electrode S4-1, the third sub-drain electrode D4-1, the third sub-channel area C4-1, and the third sub-gate electrode G4-1 may define a third sub-transistor T4-1. The fourth sub-source electrode S4-2, the fourth sub-drain electrode D4-2, the fourth sub-channel area C4-2, and the fourth sub-gate electrode G4-2 may define a fourth sub-transistor T4-2. The third sub-transistor T4-1 and the fourth sub-transistor T4-2 may define a fourth transistor T4. That is, the fourth transistor T4 may have a dual-gate structure including two gate electrodes.

The second gate line GIL may include a second line portion GIL1 extending in the first direction DR1 and a second protrusion portion GIL2 protruding from second line portion GIL1 in the second direction DR2. The third sub-gate electrode G4-1 may be a portion of the second protrusion portion GIL2 and the second line portion GIL1, and the fourth sub-gate electrode G4-2 may be a portion of the second line portion GILL.

In an embodiment, a third length L3 of the third sub-gate electrode G4-1 in the second direction DR2 may be longer than a fourth length L4 of the fourth sub-gate electrode G4-2 in the second direction DR2. For example, an area of the third sub-gate electrode G4-1 overlapping the first active pattern AP1 in the plan view may be greater than an area of the fourth sub-gate electrode G4-2 overlapping the first active pattern AP1 in the plan view. For example, a length of the third sub-gate electrode G4-1 in the first direction DR1 overlapping the first active pattern AP1 in the plan view may be substantially the same as a length of the fourth sub-gate electrode G4-2 in the first direction DR1 overlapping the first active pattern AP1 in the plan view.

In other words, a third length L3 of the third sub-channel area C4-1 in the second direction DR2 may be longer than a fourth length L4 of the fourth sub-channel area C4-2 in the second direction DR2. In other words, a third length L3 of the second protrusion portion GIL2 and the second line portion GIL1 in the second direction DR2 may be longer than a fourth length L4 of the second line portion GIL1 in the second direction DR2.

The light emitting line EML may include a fifth gate electrode G5 overlapping the fifth channel area C5 in a plan view and a sixth gate electrode G6 overlapping the sixth channel area C6 in a plan view.

The third gate line GBL may include a seventh gate electrode G7 overlapping the seventh channel area C7 in a plan view and an eighth gate electrode G8 overlapping the eighth channel area C8 in a plan view.

A fourth insulating layer IL4 and a second conductive layer SD2 may be sequentially disposed on the first insulating layer IL1 and the first gate layer GAT1. The second conductive layer SD2 may include a ninth connection pattern CP9, a first power voltage line ELVDDL, a data line DL, and a first initialization voltage line VINTL1.

In an embodiment, the second conductive layer SD2 may overlap at least a portion of the first sub-transistor T3-1, the second sub-transistor T3-2, the third sub-transistor T4-1, or the fourth sub-transistor T4-2 in a plan view.

For example, the first power voltage line ELVDDL may overlap the first, second, and third sub-transistors T3-1, T3-2, and T4-1 in a plan view. For example, the first power voltage line ELVDDL may overlap the first, second, and third sub-gate electrodes G3-1, G3-2, and G4-1 and the first, second, and third sub-channel areas C3-1, C3-2, and C4-1 in a plan view, and may shield upper portions of the first, second, and third sub-gate electrodes G3-1, G3-2, and G4-1 and the first, second, and third sub-channel areas C3-1, C3-2, and C4-1.

For example, the data line DL may overlap the fourth sub-transistor T4-2 in a plan view. For example, the data line DL may overlap the fourth sub-gate electrode G4-2 and the fourth sub-channel area C4-2 in a plan view, and may shield upper portions of the fourth sub-gate electrode G4-2 and the fourth sub-channel area C4-2.

The display device 30 according to an embodiment of the present disclosure may include the third transistor T3 including the first and second sub-transistors T3-1 and T3-2 and the fourth transistor T4 including the third and fourth sub-transistors T4-1 and T4-2. As the third sub-channel area C4-1 of the third sub-transistor T4-1 may have a relatively long length, leakage current that occurs in the fourth transistor T4 may be reduced. In addition, as the second conductive layer SD2 may shield the third and fourth transistors T3 and T4, leakage current that occurs in the third and fourth transistors T3 and T4 due to external light may be reduced. Accordingly, deterioration of display quality due to the leakage current may be minimized, and display quality of the display device 30 may be effectively improved by displaying an image with uniform luminance.

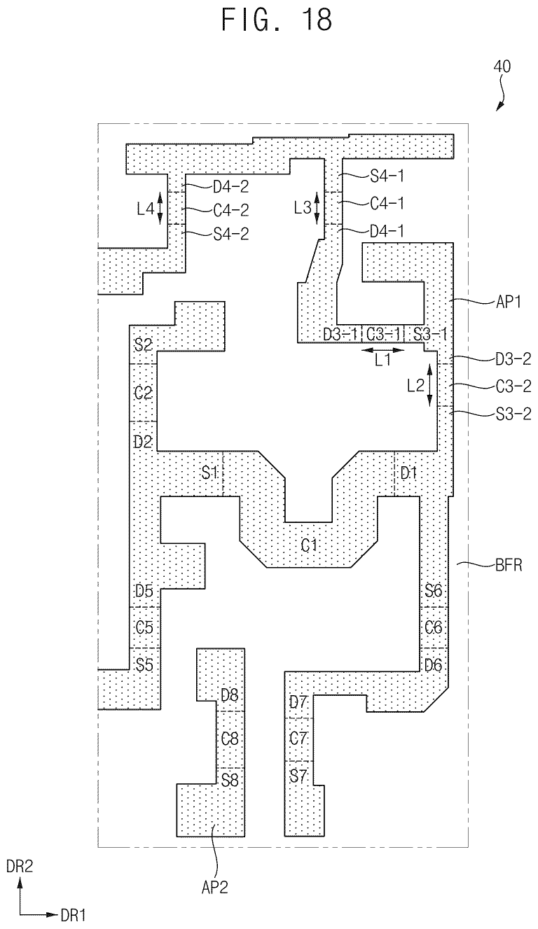

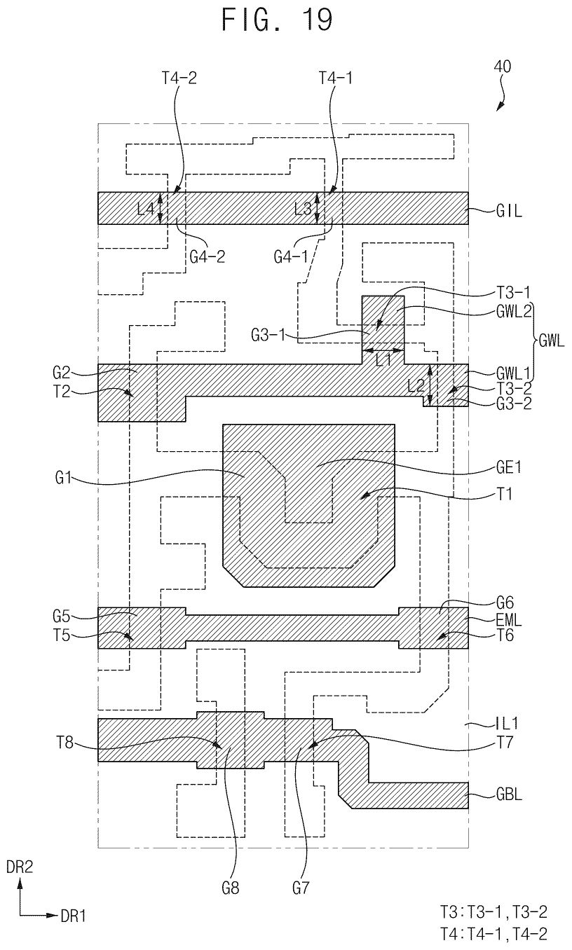

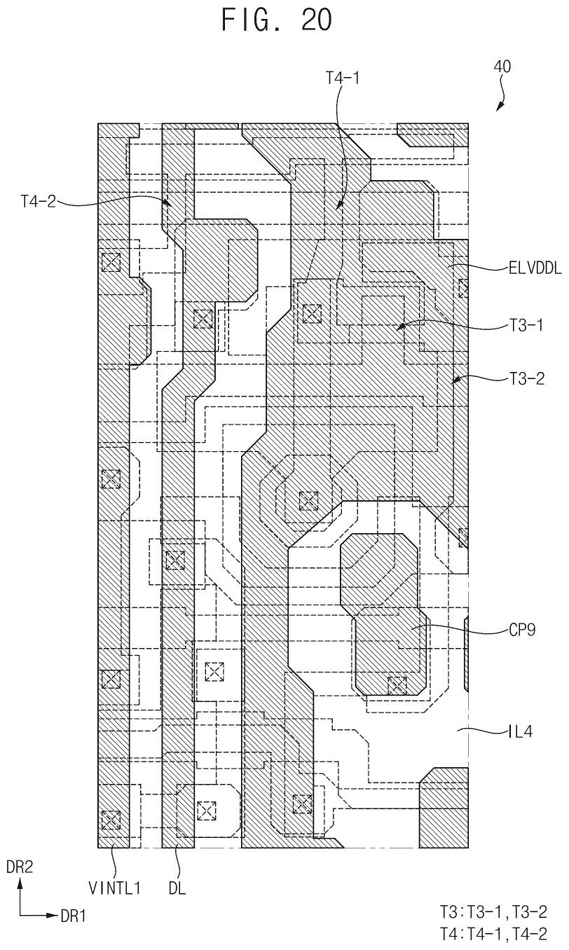

FIGS. 18, 19, and 20 are diagrams illustrating a display device according to yet another embodiment of the present disclosure. For example, FIG. 18 may be a layout diagram corresponding to FIG. 4, FIG. 19 may be a layout diagram corresponding to FIG. 5, and FIG. 20 may be a layout diagram corresponding to FIG. 8. That is, FIGS. 18, 19, and 20 may be layout diagrams illustrating a pixel included in a display device 40.

The display device 40 described with reference to FIGS. 18, 19, and 20 may be substantially the same as or similar to the display device 10 described with reference to FIGS. 1 to 11, except for the third transistor T3 and the fourth transistor T4. Hereinafter, redundant descriptions will be omitted or simplified.

Referring to FIGS. 18, 19, and 20, an active layer APL may be disposed on a buffer layer BFR. The active layer APL may include a first active pattern AP1 and a second active pattern AP2.

The first active pattern AP1 may include a first source electrode S1, a first drain electrode D1, a first channel area C1, a second source electrode S2, a second drain electrode D2, a second channel area C2, a first sub-source electrode S3-1, a first sub-drain electrode D3-1, a first sub-channel area C3-1, a second sub-source electrode S3-2, a second sub-drain electrode D3-2, a second sub-channel area C3-2, a third sub-source electrode S4-1, a third sub-drain electrode D4-1, a third sub-channel area C4-1, a fourth sub-source electrode S4-2, a fourth sub-drain electrode D4-2, a fourth sub-channel area C4-2, a fifth source electrode S5, a fifth drain electrode D5, a fifth channel area C5, a sixth source electrode S6, a sixth drain electrode D6, a sixth channel area C6, a seventh source electrode S7, a seventh drain electrode D7, and a seventh channel area C7. The second active pattern AP2 may include an eighth source electrode S8, an eighth drain electrode D8, and an eighth channel area C8.

A first insulating layer IL1 and a first gate layer GAT1 may be sequentially disposed on the buffer layer BFR and the active layer APL. The first gate layer GAT1 may include a first gate pattern GE1, a first gate line GWL, a second gate line GIL, a light emitting line EML, and a third gate line GBL.

The first gate pattern GE1 may include a first gate electrode G1 overlapping the first channel area C1 in a plan view.

The first gate line GWL may include a second gate electrode G2 overlapping the second channel area C2 in a plan view, a first sub-gate electrode G3-1 overlapping the first sub-channel area C3-1 in a plan view, and a second sub-gate electrode G3-2 overlapping the second sub-channel area C3-2 in a plan view.

The first sub-source electrode S3-1, the first sub-drain electrode D3-1, the first sub-channel area C3-1, and the first sub-gate electrode G3-1 may define a first sub-transistor T3-1. The second sub-source electrode S3-2, the second sub-drain electrode D3-2, the second sub-channel area C3-2, and the second sub-gate electrode G3-2 may define a second sub-transistor T3-2. The first sub-transistor T3-1 and the second sub-transistor T3-2 may define a third transistor T3. That is, the third transistor T3 may have a dual-gate structure including two gate electrodes.

The first gate line GWL may include a line portion GWL1 extending in a first direction DR1 and a protrusion portion GWL2 protruding from the line portion GWL1 in a second direction DR2 intersecting the first direction DR1. The first sub-gate electrode G3-1 may be a portion of the protrusion portion GWL2, and the second sub-gate electrode G3-2 may be a portion of the line portion GWL1.

In an embodiment, a first length L1 of the first sub-gate electrode G3-1 in the first direction DR1 may be substantially the same as a second length L2 of the second sub-gate electrode G3-2 in the second direction DR2. For example, an area of the first sub-gate electrode G3-1 overlapping the first active pattern AP1 in the plan view may be substantially the same as an area of the second sub-gate electrode G3-2 overlapping the first active pattern AP1 in the plan view. For example, a length of the first sub-gate electrode G3-1 in the second direction DR2 overlapping the first active pattern AP1 in the plan view may be substantially the same as a length of the second sub-gate electrode G3-2 in the first direction DR1 overlapping the first active pattern AP1 in the plan view.

In other words, a first length L1 of the first sub-channel area C3-1 in the first direction DR1 may be substantially the same as a second length L2 of the second sub-channel area C3-2 in the second direction DR2. In other words, a first length L1 of the protrusion portion GWL2 in the first direction DR1 may be substantially the same as a second length L2 of the line portion GWL1 in the second direction DR2.

The second gate line GIL may include a third sub-gate electrode G4-1 overlapping the third sub-channel area C4-1 in a plan view and a fourth sub-gate electrode G4-2 overlapping the fourth sub-channel area C4-2 in a plan view.

The third sub-source electrode S4-1, the third sub-drain electrode D4-1, the third sub-channel area C4-1, and the third sub-gate electrode G4-1 may define a third sub-transistor T4-1. The fourth sub-source electrode S4-2, the fourth sub-drain electrode D4-2, the fourth sub-channel area C4-2, and the fourth sub-gate electrode G4-2 may define a fourth sub-transistor T4-2. The third sub-transistor T4-1 and the fourth sub-transistor T4-2 may define a fourth transistor T4. That is, the fourth transistor T4 may have a dual-gate structure including two gate electrodes.

In an embodiment, a third length L3 of the third sub-gate electrode G4-1 in the second direction DR2 may be substantially the same as a fourth length L4 of the fourth sub-gate electrode G4-2 in the second direction DR2. For example, an area of the third sub-gate electrode G4-1 overlapping the first active pattern AP1 in the plan view may be substantially the same as an area of the fourth sub-gate electrode G4-2 overlapping the first active pattern AP1 in the plan view. For example, a length of the third sub-gate electrode G4-1 in the first direction DR1 overlapping the first active pattern AP1 in the plan view may be substantially the same as a length of the fourth sub-gate electrode G4-2 in the first direction DR1 overlapping the first active pattern AP1 in the plan view. In other words, a third length L3 of the third sub-channel area C4-1 in the second direction DR2 may be substantially the same as a fourth length L4 of the fourth sub-channel area C4-2 in the second direction DR2.

The light emitting line EML may include a fifth gate electrode G5 overlapping the fifth channel area C5 in a plan view and a sixth gate electrode G6 overlapping the sixth channel area C6 in a plan view.

The third gate line GBL may include a seventh gate electrode G7 overlapping the seventh channel area C7 in a plan view and an eighth gate electrode G8 overlapping the eighth channel area C8 in a plan view.

A fourth insulating layer IL4 and a second conductive layer SD2 may be sequentially disposed on the first insulating layer IL1 and the first gate layer GAT1. The second conductive layer SD2 may include a ninth connection pattern CP9, a first power voltage line ELVDDL, a data line DL, and a first initialization voltage line VINTL1.

In an embodiment, the second conductive layer SD2 may overlap at least a portion of the first sub-transistor T3-1, the second sub-transistor T3-2, the third sub-transistor T4-1, or the fourth sub-transistor T4-2 in a plan view.

For example, the first power voltage line ELVDDL may overlap the first, second, and third sub-transistors T3-1, T3-2, and T4-1 in a plan view. For example, the first power voltage line ELVDDL may overlap the first, second, and third sub-gate electrodes G3-1, G3-2, and G4-1 and the first, second, and third sub-channel areas C3-1, C3-2, and C4-1 in a plan view, and may shield upper portions of the first, second, and third sub-gate electrodes G3-1, G3-2, and G4-1 and the first, second, and third sub-channel areas C3-1, C3-2, and C4-1.

For example, the data line DL may overlap the fourth sub-transistor T4-2 in a plan view. For example, the data line DL may overlap the fourth sub-gate electrode G4-2 and the fourth sub-channel area C4-2 in a plan view, and may shield upper portions of the fourth sub-gate electrode G4-2 and the fourth sub-channel area C4-2.

The display device 40 according to an embodiment of the present disclosure may include the second conductive layer SD2 shielding upper portions of the third transistor T3 including the first and second sub-transistors T3-1 and T3-2 and the fourth transistor T4 including the third and fourth sub-transistors T4-1 and T4-2. Accordingly, leakage current that occurs in the third and fourth transistors T3 and T4 due to external light may be reduced. Accordingly, deterioration of display quality due to the leakage current may be minimized, and display quality of the display device 40 may be effectively improved by displaying an image with uniform luminance.

The display devices 10, 20, 30, and 40 according to embodiments of the present disclosure may be applied to various electronic devices. An electronic device according to an embodiment of the present disclosure may include the display device 10, the display device 20, the display device 30, or the display device 40 described above, and may further include a module or device having additional functions in addition to the display device 10, the display device 20, the display device 30, or the display device 40.

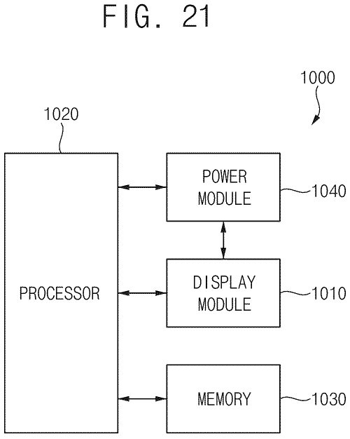

FIG. 21 is a block diagram illustrating an electronic device according to an embodiment of the present disclosure.

Referring to FIG. 21, an electronic device 1000 may include a display module 1010, a processor 1020, a memory 1030, and a power module 1040.

The processor 1020 may include at least one of a central processing unit (CPU), an application processor (AP), a graphic processing unit (GPU), a communication processor (CP), an image signal processor (ISP), and a controller.

The memory 1030 may store data information necessary for an operation of the processor 1020 or the display module 1010. When the processor 1020 executes an application stored in the memory 1030, an image data signal and/or an input control signal may be transmitted to the display module 1010, and the display module 1010 may process the received signal and output image information through a display screen.

The power module 1040 may include a power supply module such as a power adapter, a battery device, or the like and a power conversion module that converts power supplied by the power supply module to generate power necessary for an operation of the electronic device 1000.

At least one of the components of the electronic device 1000 described above may be included in the display device according to embodiments described above. In addition, some of individual modules functionally included in one module may be included in the display device, and others may be provided separately from the display device. For example, the display device may include the display module 1010, and the processor 1020, the memory 1030, and the power module 1040 may be provided in form of other devices in the electronic device 1000 other than the display device.

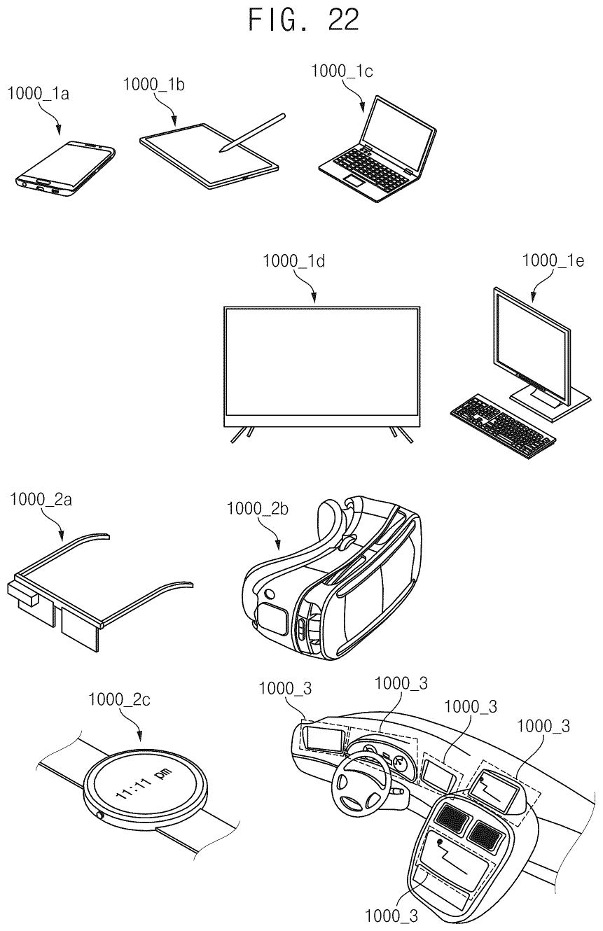

FIG. 22 is a schematic diagram illustrating electronic devices according to embodiments of the present disclosure.

Referring to FIG. 22, various electronic devices to which the display device according to embodiments of the present disclosure is applied may include not only an image display electronic device, but also a wearable electronic device including a display module, a vehicle electronic device 1000_3 including a display module, or the like. The image display electronic device may be a smartphone 1000_1a, a tablet PC 1000_1b, a laptop 1000_1c, a TV 1000_1d, a desk monitor 1000_1e, or the like. The wearable electronic device may be smart glasses 1000_2a, a head mounted display 1000_2b, a smart watch 1000_2c, or the like. The vehicle electronic device 1000_3 may be a center information display (CID) disposed on a dashboard and center fascia of a vehicle, a room mirror display, or the like.

The present disclosure can be applied to various display devices and electronic devices. For example, the present disclosure is applicable to various display devices such as display devices for vehicles, ships and aircraft, portable communication devices, display devices for exhibition or information transmission, medical display devices, and the like.

The foregoing is illustrative of embodiments and is not to be construed as limiting thereof. Although a few embodiments have been described, those skilled in the art will readily appreciate that many modifications are possible in the embodiments without materially departing from the novel teachings and advantages of the present invention. Accordingly, all such modifications are intended to be included within the scope of the present invention as defined in the claims. Therefore, it is to be understood that the foregoing is illustrative of various embodiments and is not to be construed as limited to the specific embodiments disclosed, and that modifications to the disclosed embodiments, as well as other embodiments, are intended to be included within the scope of the appended claims.

What is claimed is:

1. A display device comprising:
an active pattern;
a first gate line;
a power voltage line;
a light emitting element;
a first transistor electrically connected to the power voltage line and the light emitting element; and
a second transistor electrically connected to the first gate line and including:
a first sub-transistor electrically connected to the first transistor and including a first sub-gate electrode; and
a second sub-transistor connected in series with the first sub-transistor and including a second sub-gate electrode spaced apart from the first sub-gate electrode,
wherein an area in which the first sub-gate electrode overlaps the active pattern in a plan view is greater than an area in which the second sub-gate electrode overlaps the active pattern in the plan view.

2. The display device of claim 1, wherein
the first gate line includes a first line portion extending in a first direction and a first protrusion portion protruding from the first line portion in a second direction intersecting the first direction,
the first sub-gate electrode is a portion of the first protrusion portion, and
the second sub-gate electrode is a portion of the first line portion.

3. The display device of claim 2, wherein a length of the first sub-gate electrode in the first direction is longer than a length of the second sub-gate electrode in the second direction.

4. The display device of claim 2, wherein a length of the first sub-gate electrode in the second direction is longer than a length of the second sub-gate electrode in the second direction.

5. The display device of claim 2, wherein a length of the first protrusion portion in the first direction is longer than a length of the first line portion in the second direction.

6. The display device of claim 3, further comprising:
a second gate line; and
a third transistor electrically connected to the second gate line and including:
a third sub-transistor electrically connected to the first transistor and including a third sub-gate electrode; and
a fourth sub-transistor connected in series with the third sub-transistor and including a fourth sub-gate electrode spaced apart from the third sub-gate electrode.

7. The display device of claim 6, wherein an area in which the third sub-gate electrode overlaps the active pattern in the plan view is greater than an area in which the fourth sub-gate electrode overlaps the active pattern in the plan view.

8. The display device of claim 6, wherein a length of the third sub-gate electrode in the second direction is longer than a length of the fourth sub-gate electrode in the second direction.

9. The display device of claim 6, wherein
the second gate line includes a second line portion extending in the first direction and a second protrusion portion protruding from the second line portion in the second direction,
the third sub-gate electrode is a portion of the second protrusion portion and the second line portion, and
the fourth sub-gate electrode is a portion of the second line portion.

10. The display device of claim 9, wherein a length of the second protrusion portion and the second line portion in the second direction is longer than a length of the second line portion in the second direction.

11. The display device of claim 6, wherein the first sub-gate electrode, the second sub-gate electrode, the third sub-gate electrode, and the fourth sub-gate electrode are disposed in a same layer.

12. The display device of claim 1, wherein the second sub-transistor is electrically connected to the first transistor through the first sub-transistor.

13. A display device comprising:
an active pattern;
a gate layer disposed on the active pattern and including a first gate line and a second gate line;
a conductive layer disposed on the gate layer and including a power voltage line; and
a pixel electrode disposed on the conductive layer,
wherein the active pattern and the gate layer define:
a first transistor electrically connected to the power voltage line and the pixel electrode;
a second transistor electrically connected to the first gate line and including:
a first sub-transistor electrically connected to the first transistor and including a first sub-gate electrode; and
a second sub-transistor connected in series with the first sub-transistor and including a second sub-gate electrode spaced apart from the first sub-gate electrode; and
a third transistor electrically connected to the second gate line and including:
a third sub-transistor electrically connected to the first transistor and including a third sub-gate electrode; and
a fourth sub-transistor connected in series with the third sub-transistor and including a fourth sub-gate electrode spaced apart from the third sub-gate electrode, and
the conductive layer overlaps at least one of the first sub-transistor, the second sub-transistor, the third sub-transistor, or the fourth sub-transistor in a plan view.

14. The display device of claim 13, wherein the power voltage line overlaps the first sub-transistor, the second sub-transistor, and the third sub-transistor in the plan view.

15. The display device of claim 13, wherein
the conductive layer further includes a data line, and
the data line overlaps the fourth sub-transistor in the plan view.

16. The display device of claim 13, wherein the pixel electrode overlaps at least one of the first sub-transistor, the second sub-transistor, the third sub-transistor, or the fourth sub-transistor in the plan view.

17. The display device of claim 13, wherein
the first gate line includes a first line portion extending in a first direction and a first protrusion portion protruding from the first line portion in a second direction intersecting the first direction,
the first sub-gate electrode is a portion of the first protrusion portion, and
the second sub-gate electrode is a portion of the first line portion.

18. The display device of claim 17, wherein an area in which the first sub-gate electrode overlaps the active pattern in the plan view is greater than an area in which the second sub-gate electrode overlaps the active pattern in the plan view.

19. The display device of claim 17, wherein a length of the first sub-gate electrode in the first direction is longer than a length of the second sub-gate electrode in the second direction.

20. The display device of claim 13, wherein
the second gate line includes a second line portion extending in a first direction and a second protrusion portion protruding from the second line portion in a second direction intersecting the first direction,
the third sub-gate electrode is a portion of the second protrusion portion and the second line portion, and
the fourth sub-gate electrode is a portion of the second line portion.

21. The display device of claim 20, wherein an area in which the third sub-gate electrode overlaps the active pattern in the plan view is greater than an area in which the fourth sub-gate electrode overlaps the active pattern in the plan view.

22. The display device of claim 20, wherein a length of the third sub-gate electrode in the second direction is longer than a length of the fourth sub-gate electrode in the second direction.

23. An electronic device comprising:
a display device; and
a power module that supplies power to the display device,
wherein the display device includes:
an active pattern;
a first gate line;
a power voltage line;
a light emitting element;
a first transistor electrically connected to the power voltage line and the light emitting element; and
a second transistor electrically connected to the first gate line and including:
a first sub-transistor electrically connected to the first transistor and including a first sub-gate electrode; and
a second sub-transistor connected in series with the first sub-transistor and including a second sub-gate electrode spaced apart from the first sub-gate electrode,
wherein an area in which the first sub-gate electrode overlaps the active pattern in a plan view is greater than an area in which the second sub-gate electrode overlaps the active pattern in the plan view.
